(19) United States
(12) Patent Application Publication
(10) Pub. No.: US 2026/0190807 A1
(43) Pub. Date: Jul. 2, 2026

(54) DISPLAY DEVICE, DISPLAY SYSTEM, AND METHOD OF MANUFACTURING THE DISPLAY DEVICE

(71) Applicant: SAMSUNG DISPLAY CO., LTD., YONGIN-SI (KR)

(72) Inventors: Ju Youn SON, Yongin-si (KR); Hyo Joon KIM, Yongin-si (KR); Soon Gi PARK, Yongin-si (KR); Ju Hwa HA, Yongin-si (KR)

(21) Appl. No.: 19/289,182

(22) Filed: Aug. 4, 2025

(30) Foreign Application Priority Data
Dec. 26, 2024 (KR) 10-2024-0197502

(51) Int. Cl. H10K 59/80; H10K 59/12

(52) U.S. Cl. CPC H10K 59/879; H10K 59/1201

(57) ABSTRACT

A display device includes a display panel and a pancake lens arranged on the display panel. The pancake lens includes a plurality of lenses and an optical film arranged on a surface of at least one of the plurality of lenses. The optical film has a cut surface where a portion of the optical film has been cut. In a plan view, the cut surface does not overlap with the display panel.

### CROSS-REFERENCE TO RELATED APPLICATION

This application claims priority under 35 U.S.C. § 119 to Korean Patent Application No. 10-2024-0197502, filed on Dec. 26, 2024 in the Korean Intellectual Property Office, the disclosure of which is incorporated by reference in its entirety herein.

### TECHNICAL FIELD

Various embodiments of the present disclosure relate to a display device, a display system, and a method of manufacturing the display device.

### DISCSSION OF RELATED ART

A display device is an electronic device that displays images and may serve as a connection medium between a user and information. The importance of display devices has increased along with the advancement of the information society. Accordingly, the use of display devices such as a liquid crystal display device, an organic light emitting display device, and the like has been increasing.

Recently, a Head-Mounted Display (HMD) device has been developed. The HMD device is a display device which is worn by a user in the form of glasses or a helmet to form a focus on a short distance in front of eyes of the user and which implements Virtual Reality (VR), Augmented Reality (AR), or Mixed Reality (MR). A high-resolution panel is applied to the HMD device, and a pancake lens for high immersion can be applied.

### SUMMARY

An aspect of the present disclosure provides a display device capable of reducing a risk of inflection of a Chief Ray Angle (CRA) occurring, a display system, and a method of manufacturing the display device.

An aspect of the present disclosure provides a display device capable of reducing a risk of bubbles being generated when forming an optical film, a display system, and a method of manufacturing the display device.

The technical problems of the present disclosure are not limited to the technical problems as mentioned above, and other technical problems that are not mentioned will be apparent to those skilled in the art from the following descriptions.

According to an embodiment of the present disclosure, a display device includes a display panel and a pancake lens arranged on the display panel. The pancake lens includes a plurality of lenses and an optical film arranged on a surface of at least one of the plurality of lenses. The optical film has a cut surface where a portion of the optical film has been cut. In a plan view, the cut surface does not overlap with the display panel.

According to an embodiment, the surface of the at least one of the plurality of lenses may be a curved surface.

According to an embodiment, the curved surface may include a curvature change area. The curvature change area may correspond to an area including an inflection point at which curvature of the curved surface changes, or may correspond to an area in which a slope of the curved surface varies in an amount greater than or equal to about 10°.

According to an embodiment, the optical film may be attached to the surface of the at least one of the plurality of lenses.

According to an embodiment, in the plan view, the optical film may completely overlap with the display panel and may not overlap with a partial area of the at least one of the plurality of lenses.

According to an embodiment, the partial area may correspond to an outermost edge of the at least one of the plurality of lenses.

According to an embodiment, in the plan view, the cut surface may be arranged between a curvature effective diameter area of the at least one of the plurality of lenses and a flange portion of the at least one of the plurality of lenses. In the plan view, the curvature effective diameter area may correspond to an area that the display panel is arranged, and the flange portion may correspond to an area that is a predetermined distance away from an outermost edge of the at least one of the plurality of lenses.

According to an embodiment, the cut surface may include at least one of a flat surface or a curved surface in the plan view.

According to an embodiment, the optical film may include a first portion and a second portion projecting from the first portion in the plan view. The second portion may have a shape of at least one of a circle, a rectangle, or an ellipse in the plan view.

According to an embodiment, the optical film may include a plurality of cut areas.

According to an embodiment, the optical film may be thermally bonded to or attached through an adhesive layer to the surface of the at least one of the plurality of lenses.

According to an embodiment, the plurality of lenses may include at least one of plastic or glass, and the optical film may be a polarizing layer.

According to an embodiment, the display panel may include an organic light-emitting diode (OLED).

According to an embodiment of the present disclosure, a method of manufacturing a display device may include forming a display panel and forming a pancake lens on the display panel. The forming of the pancake lens includes arranging a plurality of lenses, and arranging an optical film on a surface of the at least one of the plurality of lenses. The arranging of the optical film includes forming the optical film having a cut surface by cutting a portion of a base optical film, and in a plan view, the cut surface does not overlap with the display panel.

According to an embodiment, the arranging of the optical film may further include attaching the optical film to the surface of the at least one of the plurality of lenses by thermal bonding or through an adhesive layer. The surface of the at least one of the plurality of lenses may be a curved surface and the curved surface may include a curvature change area. The curvature change area may correspond to an area including an inflection point where a curvature of the curved surface changes, or may correspond to an area where a slope of the curved surface varies in an amount greater than or equal to about 10°.

According to an embodiment, in the plan view, the optical film may completely overlap with the display panel and may not overlap with a partial area of the at least one of the plurality of lenses. The partial area may correspond to an outermost edge of the at least one of the plurality of lenses. In the plan view, the cut surface may be arranged between a curvature effective diameter area of the at least one of the plurality of lenses and a flange portion of the at least one of the plurality of lenses. In the plan view, the curvature effective diameter area may correspond to an area that the display panel is arranged. The flange portion may correspond to an area that is a predetermined distance away from the outermost edge of the at least one of the plurality of lenses.

According to an embodiment, the cut surface may include at least one of a flat surface or a curved surface in the plan view.

According to an embodiment of the present disclosure, a display system includes a display panel and a pancake lens arranged on the display panel. The pancake lens includes a plurality of lenses and an optical film arranged on a surface of at least one of the plurality of lenses. The surface of the at least one of the plurality of lenses is a curved surface. The optical film has a cut surface where a portion of the optical film has been cut. In a plan view, the cut surface is arranged between a curvature effective diameter area of the at least one of the plurality of lenses and a flange portion of the at least one of the plurality of lenses. In the plan view, the curvature effective diameter area corresponds to an area that the display panel is arranged. The flange portion corresponds to an area that is a predetermined distance away from an outermost edge of the at least one of the plurality of lenses.

According to an embodiment, the display system may include at least one of a Virtual Reality (VR) device, a Mixed Reality (MR) device, or an Augmented Reality (AR) device.

According to an embodiment, in a plan view, the optical film may overlap with an area that an image is displayed to a user and may not overlap with the outermost edge of the at least one of the plurality of lenses.

According to an embodiment of the present disclosure, an electronic device includes a processor. A memory has stored application programs for execution by the processor. A display device includes a display panel. A pancake lens is arranged on the display panel. The pancake lens comprises a plurality of lenses. An optical film is arranged on a surface of at least one of the plurality of lenses. The optical film has a cut surface where a portion of the optical film has been cut. In a plan view, the cut surface does not overlap with the display panel.

### BRIEF DESCRIPTION OF THE DRAWINGS

FIG. 1 is a schematic block diagram illustrating a display device according to an embodiment of the present disclosure.

FIG. 2 is a schematic block diagram illustrating one of sub-pixels of FIG. 1 according to an embodiment of the present disclosure.

FIG. 3 is a schematic diagram illustrating an equivalent circuit of a sub-pixel of FIG. 2 according to an embodiment of the present disclosure.

FIG. 4 is a schematic plan view illustrating a display panel of FIG. 1 according to an embodiment of the present disclosure.

FIG. 5 is a schematic exploded perspective view of a portion of a display panel of FIG. 4 according to an embodiment of the present disclosure.

FIG. 6 is a schematic plan view of one of pixels of FIG. 5 according to an embodiment of the present disclosure.

FIG. 7 is a schematic cross-sectional view taken along line I-I′ of FIG. 6 according to an embodiment of the present disclosure.

FIG. 8 is a schematic cross-sectional view taken along line I-I′ of FIG. 6 according to an embodiment of the present disclosure.

FIG. 9 is a schematic enlarged view of area A of FIG. 8 according to an embodiment of the present disclosure.

FIG. 10 is a schematic cross-sectional view showing a portion of a light emitting structure included in one of first to third light emitting devices of FIG. 7 or 8 according to an embodiment of the present disclosure.

FIG. 11 is a schematic cross-sectional view showing a portion of a light emitting structure included in one of the first to third light emitting devices of FIG. 7 or 8 according to an embodiment of the present disclosure.

FIG. 12 is a schematic plan view showing one of the pixels of FIG. 5 according to an embodiment of the present disclosure.

FIG. 13 is a schematic plan view showing one of the pixels of FIG. 5 according to an embodiment of the present disclosure.

FIG. 14 is a schematic cross-sectional view showing a display device according to an embodiment of the present disclosure.

FIG. 15 is a schematic cross-sectional view showing a lens according to an embodiment of the present disclosure.

FIGS. 16 to 18 are schematic diagrams illustrating an arrangement of a lens and an optical film according to embodiments of the present disclosure.

FIG. 19 is a diagram illustrating a case where an optical film which does not include a cut area is arranged on a lens.

FIG. 20 is diagram illustrating a case where an optical film which includes a cut area is arranged on a lens according to an embodiment of the present disclosure.

FIG. 21 is a flowchart illustrating a method of manufacturing a display device according to an embodiment of the present disclosure.

FIG. 22 is a block diagram illustrating a display system according to an embodiment of the present disclosure.

FIG. 23 is a schematic perspective view showing an application example of the display system of FIG. 22 according to an embodiment of the present disclosure.

FIG. 24 is a schematic diagram illustrating a head-mounted display device worn by a user of FIG. 23 according to an embodiment of the present disclosure.

### DETAILED DESCRIPTION OF EMBODIMENTS

Hereinafter, embodiments according to the present disclosure are described in detail with reference to the accompanying drawings. It should be noted that in the following description, only portions necessary for understanding an operation according to the present disclosure may be described, and descriptions of other portions may be omitted in order not to obscure the subject matter of the present disclosure. In addition, the present disclosure may be embodied in other forms without being limited to embodiments described herein. However, non-limiting embodiments of the present disclosure are described in detail in order for those skilled in the art to be able to readily implement the technical spirit of the present disclosure.

Throughout the specification, in a case where a component is “connected” to another component, the components may be “directly connected” or the components may be “indirectly connected” with another element interposed therebetween. Terms used herein are for describing specific embodiments and are not intended to limit the present disclosure. Throughout the specification, in a case where a certain portion “includes” a certain component, the portion may further include another component without excluding another component unless otherwise stated. “At least one of X, Y, and Z” and “at least one selected from a group consisting of X, Y, and Z” may be interpreted as X only, Y only, Z only, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features may be positioned in a direction “on” the other elements or features. Therefore, in an embodiment, the term “under” may include both directions of on and under. In addition, the device may face in other directions (for example, rotated 90 degrees or in other directions) and thus the spatially relative terms used herein may be interpreted according thereto.

In addition, embodiments of the disclosure may be described here with reference to schematic diagrams (and intermediate structures) of the present disclosure, so that changes in a shape as shown due to, for example, manufacturing technology and/or a tolerance may be expected. Therefore, embodiments disclosed herein may not be construed as being limited to shown specific shapes, and should be interpreted as including, for example, changes in shapes that occur as a result of manufacturing. As described herein, the shapes shown in the drawings may not show actual shapes of areas of a device, and embodiments are not necessarily limited thereto.

The present disclosure concerns a display device that includes a pancake lens having an optical film arranged on a curved surface of a lens. The optical film has a cut surface where a portion of the optical film has been cut. The cut surface reduces the risk of bubbles being generated when forming the optical film. Therefore, the display device may have increased reliability and may display high quality images. The curved surface of the lens includes a curvature change area which reduces the risk of the occurrence of inflection of a Chief Ray Angle (CRA).

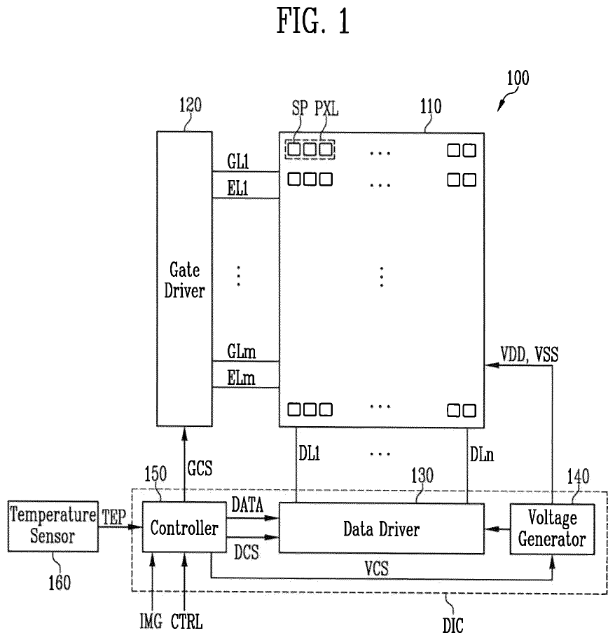

FIG. 1 is a schematic block diagram illustrating an embodiment of a display device 100.

Referring to FIG. 1, in an embodiment the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to (e.g., electrically connected thereto) the data driver 130 through first to n-th data lines DL1 to DLn.

Each of the sub-pixels SP may include at least one light emitting device configured to generate light. Accordingly, each of the sub-pixels SP may generate light of a particular color, such as red, green, blue, cyan, magenta, yellow, or the like. Two or more sub-pixels of the sub-pixels SP may constitute one pixel PXL. For example, as shown in FIG. 1, three sub-pixels may constitute one pixel PXL.

The gate driver 120 is connected to (e.g., electrically connected thereto) the sub-pixels SP arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating the start of each frame, a horizontal synchronization signal for outputting gate signals in synchronization with the timing at which data signals are applied, or the like.

In an embodiment, first to m-th emission control lines EL1 to ELm connected to the sub-pixels SP in the row direction may be further provided. In an embodiment in which the first to m-th emission control lines EL1 to ELm are further provided, the gate driver 120 may include an emission control driver configured to control the first to m-th emission control lines EL1 to ELm, and the emission control driver may operate under the control of the controller 150.

The gate driver 120 may be located on one side of the display panel 110 (e.g., in a plan view). However, embodiments of the present disclosure are not necessarily limited thereto. For example, in some embodiments the gate driver 120 may be divided into two or more drivers that are physically and/or logically divided, and such drivers may be located on one side of the display panel 110 and the other side of the display panel 110 opposite to the one side (e.g., in a plan view). As such, the gate driver 120 may be located around the display panel 110 in various forms according to embodiments.

The data driver 130 is connected to (e.g., electrically connected thereto) the sub-pixels SP arranged in a column direction through the first to n-th data lines DL1 to DLn. The data driver 130 receives image data DATA and a data control signal DCS from the controller 150. The data driver 130 operates in response to the data control signal DCS. In an embodiment, the data control signal DCS may include a source start pulse, a source shift clock, a source output enable signal, or the like.

In an embodiment, the data driver 130 may use voltages from the voltage generator 140 to apply data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the data lines DL1 to DLn. Corresponding sub-pixels SP may thus generate light corresponding to the data signals. Accordingly, an image is displayed on the display panel 110.

In an embodiment, the gate driver 120 and the data driver 130 may include complementary metal-oxide semiconductor (CMOS) circuit devices.

The voltage generator 140 may operate in response to a voltage control signal VCS from the controller 150. The voltage generator 140 is configured to generate a plurality of voltages and provide the generated voltages to components of the display device 100. For example, the voltage generator 140 may be configured to generate a plurality of voltages by receiving an input voltage from outside the display device 100 (e.g., from an external device), adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a lower voltage level than the first power voltage VDD. In some embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, in a sensing operation of sensing electrical characteristics of transistors and/or light emitting devices of the sub-pixels SP, a predetermined reference voltage may be applied to the first to n-th data lines DL1 to DLn, and the voltage generator 140 may generate such reference voltage.

The controller 150 controls various operations of the display device 100. The controller 150 receives input image data IMG and a control signal CTRL for controlling the display of the input image data IMG from the outside. The controller 150 may provide the gate control signal GCS, the data control signal DCS, and the voltage control signal VCS in response to the control signal CTRL.

The controller 150 may output the image data DATA by converting the input image data IMG to be suitable for the display device 100 or the display panel 110. In an embodiment, the controller 150 may output the image data DATA by aligning the input image data IMG to be suitable for the sub-pixels SP in units of rows.

Two or more components among the data driver 130, the voltage generator 140, and the controller 150 may be mounted in one integrated circuit. As shown in FIG. 1, in an embodiment the data driver 130, the voltage generator 140, and the controller 150 may be included in a driver integrated circuit DIC. The data driver 130, the voltage generator 140, and the controller 150 may be functionally distinct components within one driver integrated circuit DIC. In some embodiments, at least one of the data driver 130, the voltage generator 140, or the controller 150 may be provided as a component separate from the driver integrated circuit DIC.

The display device 100 may include at least one temperature sensor 160. The temperature sensor 160 is configured to sense the temperature around the temperature sensor 160 and generate temperature data TEP indicative of the sensed temperature. In an embodiment, the temperature sensor 160 may be located adjacent to the display panel 110 and/or the driver integrated circuit DIC.

The controller 150 may control various operations of the display device 100 in response to the temperature data TEP. In an embodiment, the controller 150 may adjust the luminance of the image output from the display panel 110 in response to the temperature data TEP. For example, the controller 150 may adjust the data signals and the first and second power voltages VDD and VSS by controlling components such as the data driver 130 and/or the voltage generator 140.

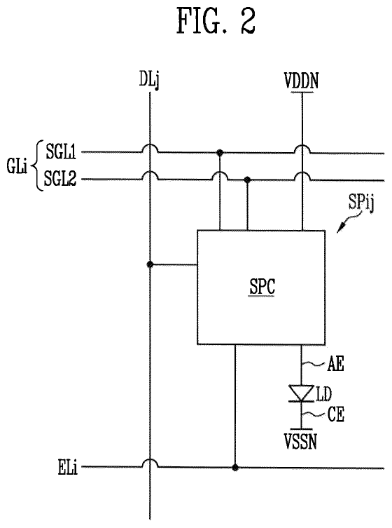

FIG. 2 is a schematic block diagram illustrating an embodiment of one of the sub-pixels SP of FIG. 1. In FIG. 2, among the sub-pixels SP in FIG. 1, a sub-pixel SPij arranged in an i-th row in which i is an integer greater than or equal to 1 and less than or equal to m and a j-th column in which j is an integer greater than or equal to 1 and less than or equal to n is shown as an example.

Referring to FIG. 2, in an embodiment the sub-pixel SPij may include a sub-pixel circuit SPC and a light emitting device LD.

The light emitting device LD is connected between a first power voltage node VDDN and a second power voltage node VSSN. In an embodiment, the first power voltage node VDDN is a node which transmits the first power voltage VDD of FIG. 1, and the second power voltage node VSSN is a node which transmits the second power voltage VSS of FIG. 1. The light emitting device LD according to the present disclosure may be an organic light-emitting diode (OLED).

An anode electrode AE of the light emitting device LD is connected to the first power voltage node VDDN through the sub-pixel circuit SPC, and a cathode electrode CE of the light emitting device LD may be connected to the second power voltage node VSSN. For example, in an embodiment the anode electrode AE of the light emitting device LD may be connected to the first power voltage node VDDN via one or more transistors included in the sub-pixel circuit SPC.

The sub-pixel circuit SPC may be connected to the i-th gate line GLi among the first to m-th gate lines GL1 to GLm of FIG. 1, the i-th emission control line ELi among the first to m-th emission control lines EL1 to ELm of FIG. 1, and the j-th data line DLj among the first to n-th data lines DL1 to DLn of FIG. 1. In an embodiment, the sub-pixel circuit SPC is configured to control the light emitting device LD according to signals received through the above-mentioned signal lines.

The sub-pixel circuit SPC may operate in response to a gate signal received via the i-th gate line GLi. The i-th gate line GLi may include one or more sub-gate lines. In an embodiment, as shown in FIG. 2, the i-th gate line GLi may include first and second sub-gate lines SGL1 and SGL2. The sub-pixel circuit SPC may operate in response to gate signals received via the first and second sub-gate lines SGL1 and SGL2. As such, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received via the i-th emission control line ELi. In an embodiment, the i-th emission control line ELi may include one or more sub-emission control lines. In an embodiment in which the i-th emission control line ELi includes two or more sub-emission control lines, the sub-pixel circuit SPC may operate in response to emission control signals received via the corresponding sub-emission control lines.

The sub-pixel circuit SPC may receive a data signal through the j-th data line DLj. The sub-pixel circuit SPC may store a voltage corresponding to the data signal in response to at least one of the gate signals received via the first and second sub-gate lines SGL1 and SGL2. In an embodiment, in response to the emission control signal received through the i-th emission control line ELi, the sub-pixel circuit SPC may adjust a current flowing from the first power voltage node VDDN through the light emitting device LD to the second power voltage node VSSN according to the stored voltage. Accordingly, the light emitting device LD may generate light of the luminance corresponding to the data signal.

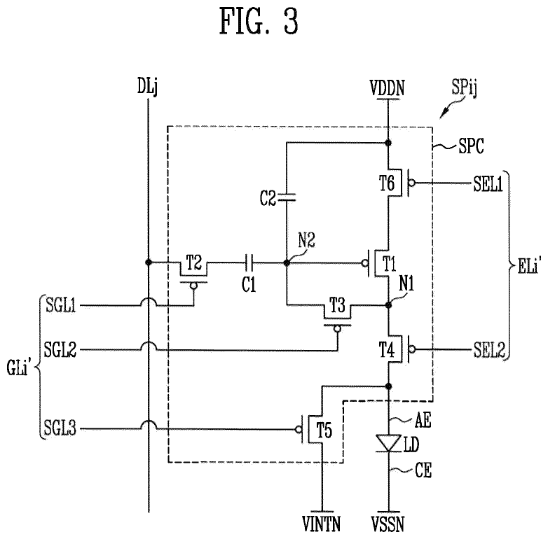

FIG. 3 is a schematic diagram illustrating an embodiment of an equivalent circuit of the sub-pixel SPij of FIG. 2.

Referring to FIG. 3, the sub-pixel SPij may include the sub-pixel circuit SPC and the light emitting device LD.

The sub-pixel circuit SPC may be connected to an i-th gate line GLi′, an i-th emission control line ELi′, and the j-th data line DLj. Compared with the i-th gate line GLi in FIG. 2, the i-th gate line GLi′ may further include a third sub-gate line SGL3. Compared with the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 is connected between the first power voltage node VDDN and a first node N1. In an embodiment, the gate of the first transistor T1 is connected to a second node N2, so that the first transistor T1 may be turned on according to a voltage level of the second node N2. The first transistor T1 may be referred to as a driving transistor.

A second transistor T2 is connected between the j-th data line DLj and the second node N2. In an embodiment, a gate of the second transistor T2 is connected to the first sub-gate line SGL1, so that the second transistor T2 may be turned on in response to the gate signal of the first sub-gate line SGL1. The second transistor T2 may be referred to as a switching transistor.

A third transistor T3 is connected between the first node N1 and the second node N2. In an embodiment, a gate of the third transistor T3 is connected to the second sub-gate line SGL2, so that the third transistor T3 may be turned on in response to the gate signal of the second sub-gate line SGL2.

A fourth transistor T4 is connected between the first node N1 and the anode electrode AE of the light emitting device LD. In an embodiment, a gate of the fourth transistor T4 is connected to the second sub-emission control line SEL2, so that the fourth transistor T4 may be turned on in response to the emission control signal of the second sub-emission control line SEL2.

A fifth transistor T5 is connected between the anode electrode AE of the light emitting device LD and an initialization voltage node VINTN. The initialization voltage node VINTN is configured to transfer an initialization voltage. In an embodiment, the initialization voltage may be provided by the voltage generator 140 of FIG. 1. In some embodiments, the initialization voltage may be provided by an external device of the display device 100. In an embodiment, a gate of the fifth transistor T5 is connected to the third sub-gate line SGL3, so that the fifth transistor T5 may be turned on in response to the gate signal of the third sub-gate line SGL3.

A sixth transistor T6 is connected between the first power voltage node VDDN and the first transistor T1. A gate of the sixth transistor T6 is connected to the first sub-emission control line SEL1, so that the sixth transistor T6 may be turned on in response to the emission control signal of the first sub-emission control line SEL1.

The first capacitor C1 is connected between the second transistor T2 and the second node N2. The second capacitor C2 is connected between the first power voltage node VDDN and the second node N2.

As described above, the sub-pixel circuit SPC may include the first to sixth transistors T1 to T6, and the first and second capacitors C1 and C2. However, embodiments of the present disclosure are not necessarily limited thereto. The sub-pixel circuit SPC may be implemented in one of a variety of forms of circuits including a plurality of transistors and one or more capacitors. For example, the sub-pixel circuit SPC may include two transistors and one capacitor. According to some embodiments of the sub-pixel circuit SPC, the number of sub-gate lines included in the i-th gate line GLi′ and the number of sub-emission control lines included in the i-th emission control line ELi′ may vary.

The first to sixth transistors T1 to T6 may be P-type transistors. Each of the first to sixth transistors T1 to T6 may be a Metal Oxide Silicon Field Effect Transistor (MOSFET). However, embodiments of the present disclosure are not necessarily limited thereto. For example, at least one of the first to sixth transistors T1 to T6 may be replaced with an N-type transistor.

In an embodiment, the first to sixth transistors T1 to T6 may include an amorphous silicon semiconductor, a monocrystalline silicon semiconductor, a polycrystalline silicon semiconductor, an oxide semiconductor, or the like.

The light emitting device LD may include the anode electrode AE, the cathode electrode CE, and an emission layer. The emission layer may be arranged between the anode electrode AE and the cathode electrode CE (e.g., in a vertical direction). In an embodiment, after the data signal transmitted through the j-th data line DLj is reflected in the voltage of the second node N2, the fourth and sixth transistors T4 and T6 may be turned on when the emission control signals of the first and second sub-emission control lines SEL1 and SEL2 are enabled to a low level. In addition, the first transistor T1 may be turned on according to the voltage of the second node N2, so that a current may flow from the first power voltage node VDDN to the second power voltage node VSSN. The light emitting device LD may emit light depending on the amount of the current flowing therethrough.

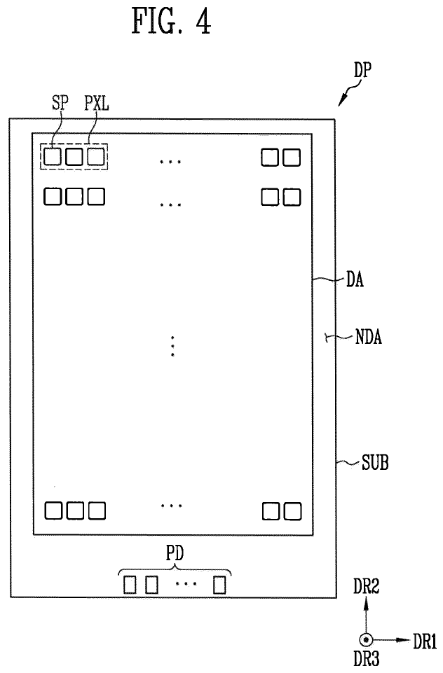

FIG. 4 is a schematic plan view illustrating an embodiment DP of the display panel 110 of FIG. 1.

Referring to FIG. 4, the embodiment DP of the display panel 110 of FIG. 1 may include a display area DA and a non-display area NDA. The display panel DP displays an image through the display area DA. The non-display area NDA is arranged around the display area DA (e.g., in a plan view).

The display panel DP may include a substrate SUB, the sub-pixels SP, and pads PD.

In an embodiment in which the display panel DP is used as a display screen of a Head-Mounted Display (HMD) device, a Virtual Reality (VR) device, a Mixed Reality (MR) device, an Augmented Reality (AR) device, or the like, the display panel DP may be located very close to a user's eyes. In this embodiment, the sub-pixels SP with a relatively high degree of integration are required. To increase the degree of integration of the sub-pixels SP, the substrate SUB may be provided as a silicon substrate. The sub-pixels SP and/or the display panel DP may be formed on the substrate SUB that is a silicon substrate. The display device 100 (see FIG. 1) including the display panel DP formed on the substrate SUB that is a silicon substrate may be referred to as an OLED on Silicon (OLEDoS) display device.

The sub-pixels SP are arranged in the display area DA on the substrate SUB. In an embodiment, the sub-pixels SP may be arranged in a matrix form in a first direction DR1 and a second direction DR2 intersecting the first direction DR1. However, embodiments of the present disclosure are not necessarily limited thereto. For example, the sub-pixels SP may be arranged in a zigzag shape in the first direction DR1 and the second direction DR2. For example, the sub-pixels SP may be arranged in a PenTile™ form. The first direction DR1 may be a row direction and the second direction DR2 may be a column direction. A third direction DR3 may be a direction in which light is emitted from the display panel DP.

Two or more sub-pixels of the plurality of sub-pixels SP may constitute one pixel PXL.

In the non-display area NDA on the substrate SUB, a component for controlling the sub-pixels SP may be arranged. For example, wirings connected to the sub-pixels SP such as the first to m-th gate lines GL1 to GLm and the first to n-th data lines DL1 to DLn of FIG. 1 may be located in the non-display area NDA.

At least one of the gate driver 120, the data driver 130, the voltage generator 140, the controller 150, and the temperature sensor 160 of FIG. 1 may be integrated in the non-display area NDA of the display panel DP. In an embodiment, the gate driver 120 of FIG. 1 may be mounted to the display panel DP and arranged in the non-display area NDA. In some embodiments, the gate driver 120 may be implemented as an integrated circuit separate from the display panel DP. In an embodiment, the temperature sensor 160 may be located in the non-display area NDA to sense the temperature of the display panel DP.

The pads PD are arranged in the non-display area NDA on the substrate SUB. The pads PD may be electrically connected to the sub-pixels SP through wirings. For example, the pads PD may be connected to the sub-pixels SP through the first to n-th data lines DL1 to DLn.

The pads PD may interface the display panel DP to other components of the display device 100 (see FIG. 1). In an embodiment, voltages and signals necessary for an operation of components included in the display panel DP may be provided from the driver integrated circuit DIC of FIG. 1 through the pads PD. For example, the first to n-th data lines DL1 to DLn may be connected to the driver integrated circuit DIC via the pads PD. For example, the first and second power voltages VDD and VSS may be received from the driver integrated circuit DIC via the pads PD. For example, in an embodiment in which the gate driver 120 is mounted on the display panel DP, the gate control signal GCS may be transmitted from the driver integrated circuit DIC to the gate driver 120 through the pads PD.

In an embodiment, a circuit board may be electrically connected to the pads PD using a conductive adhesive such as an anisotropic conductive film. The circuit board may be a flexible printed circuit board (FPCB) or a flexible film having a flexible material. The driver integrated circuit DIC may be mounted to the circuit board and electrically connected to the pads PD.

In an embodiment, the display area DA may have various shapes (e.g., in a plan view). The display area DA may have the shape of a closed loop including straight and/or curved sides. For example, in some embodiments, the display area DA may have shapes such as a polygon, a circle, a semicircle, or an ellipse.

In an embodiment, the display panel DP may have a flat display surface. In some embodiments, the display panel DP may have an at least partially rounded display surface. In an embodiment, the display panel DP may be bendable, foldable, or rollable. In such cases, the display panel DP and/or the substrate SUB may include materials with flexible properties.

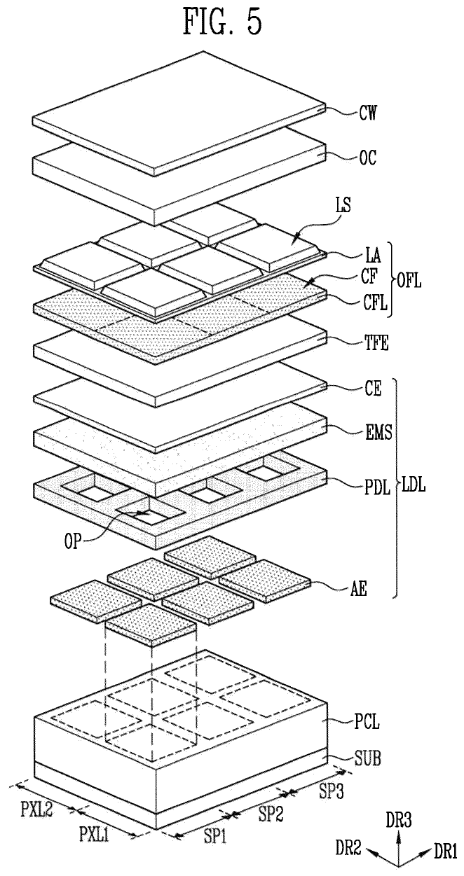

FIG. 5 is a schematic exploded perspective view of a portion of the display panel DP of FIG. 4. In FIG. 5, a portion of the display panel DP corresponding to two pixels PXL1 and PXL2 among the pixels PXL in FIG. 4 is schematically illustrated for clear and concise description. A portion of the display panel DP corresponding to the remaining pixels may be similarly configured.

Referring to FIGS. 4 and 5, each of the first and second pixels PXL1 and PXL2 may include first, second, and third sub-pixels SP1, SP2, and SP3. However, embodiments of the present disclosure are not necessarily limited thereto. For example, each of the first and second pixels PXL1 and PXL2 may include four sub-pixels, or may include two sub-pixels.

In FIG. 5, the first, second, and third sub-pixels SP1, SP2, and SP3 are shown as having square shapes and having the same sizes as each other when viewed in the third direction DR3 intersecting the first and second directions DR1 and DR2. However, embodiments of the present disclosure are not necessarily limited thereto. The first, second, and third sub-pixels SP1, SP2, and SP3 may be modified to have various shapes.

In an embodiment, the display panel DP may include the substrate SUB, a pixel circuit layer PCL, a light emitting device layer LDL, an encapsulation layer TFE, an optical functional layer OFL, an overcoat layer OC, and a cover window CW (e.g., consecutively stacked in the third direction DR3).

In an embodiment, the substrate SUB may include a silicon wafer substrate formed using a semiconductor process. The substrate SUB may include a semiconductor material suitable for forming circuit devices. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In some embodiments, the substrate SUB may include a glass substrate. In still other embodiments, the substrate SUB may include a polyimide (PI) substrate.

The pixel circuit layer PCL is located on the substrate SUB (e.g., disposed directly thereon in the third direction DR3). The substrate SUB and/or the pixel circuit layer PCL may include insulating layers and conductive patterns located between the insulating layers. The conductive patterns of the pixel circuit layer PCL may function as at least one or more of the circuit devices, wirings, or the like. The conductive patterns may include copper, but embodiments of the present disclosure are not necessarily limited thereto.

The circuit devices may include the sub-pixel circuit SPC (see FIG. 2) of each of the first, second, and third sub-pixels SP1, SP2, and SP3. The sub-pixel circuit SPC may include transistors and one or more capacitors. Each transistor may include a semiconductor portion including a source region, a drain region, and a channel region, and a gate electrode overlapping the semiconductor portion. In an embodiment in which the substrate SUB is provided as a silicon substrate, a semiconductor portion may be included in the substrate SUB, and a gate electrode may be included in the pixel circuit layer PCL as a conductive pattern of the pixel circuit layer PCL. In an embodiment in which the substrate SUB is provided as a glass substrate or a PI substrate, a semiconductor portion and a gate electrode may be included in the pixel circuit layer PCL. Each capacitor may include electrodes spaced apart from one another. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

Wirings of the pixel circuit layer PCL may include signal lines connected to each of the first, second, and third sub-pixels SP1, SP2, and SP3, for example, a gate line, an emission control line, a data line, and the like. The wirings may further include a wiring connected to the first power voltage node VDDN of FIG. 2. In addition, the wirings may further include a wiring connected to the second power voltage node VSSN of FIG. 2.

The light emitting device layer LDL may include the anode electrodes AE, a pixel defining layer PDL, a light emitting structure EMS, and the cathode electrode CE.

The anode electrodes AE may be located on the pixel circuit layer PCL (e.g., disposed directly thereon in the third direction DR3). The anode electrodes AE may directly contact circuit devices of the pixel circuit layer PCL. The anode electrodes AE may include an opaque conductive material capable of reflecting light, but embodiments of the present disclosure are not necessarily limited thereto.

The pixel defining layer PDL is arranged on (e.g., disposed directly thereon) the anode electrodes AE. The pixel defining layer PDL may include an opening OP exposing a portion of each of the anode electrodes AE. Emission areas respectively corresponding to the first to third sub-pixels SP1 to SP3 may be defined according to the openings OP of the pixel defining layer PDL. Alternatively, it may be understood that emission areas respectively corresponding to the first to third sub-pixels SP1 to SP3 are defined according to the anode electrodes AE. In an embodiment, in an area adjacent to a boundary of mutually neighboring sub-pixels, the pixel defining layer PDL may include a separator which causes a discontinuity to be formed in the light emitting structure EMS. In this case, it may be understood that emission areas respectively corresponding to the first to third sub-pixels SP1 to SP3 are defined according to the separators of the pixel defining layer PDL.

In an embodiment, the pixel defining layer PDL may include an inorganic material. In this embodiment, the pixel defining layer PDL may include a plurality of stacked inorganic layers. For example, the pixel defining layer PDL may include a silicon oxide (SiOx) and a silicon nitride (SiNx). In some embodiments, the pixel defining layer PDL may include an organic material. However, the material of the pixel defining layer PDL is not necessarily limited thereto.

The light emitting structure EMS may be located over the anode electrodes AE exposed by the openings OP of the pixel defining layer PDL. The light emitting structure EMS may include an emission layer configured to generate light, an electron transport layer configured to transport electrons, a hole transport layer configured to transport holes, and the like.

In an embodiment, the light emitting structure EMS fills the opening OP of the pixel defining layer PDL, but may be located entirely on the pixel defining layer PDL. In other words, the light emitting structure EMS may extend over the first to third sub-pixels SP1 to SP3. In this embodiment, at least one or more of the layers in the light emitting structure EMS may break or bend at boundaries between the first to third sub-pixels SP1 to SP3. However, embodiments of the present disclosure are not necessarily limited thereto. For example, portions of the light emitting structure EMS corresponding to the first to third sub-pixels SP1 to SP3 are separated from each other, each of which may be arranged in the opening OP of the pixel defining layer PDL.

The cathode electrode CE may be located on the light emitting structure EMS (e.g., disposed directly thereon in the third direction DR3). The cathode electrode CE may extend over the first to third sub-pixels SP1 to SP3. As such, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may include a metallic material or a transparent conductive material so as to have a relatively small thickness. In an embodiment, the cathode electrode CE may include at least one of a variety of transparent conductive materials, including an indium tin oxide, an indium zinc oxide, an indium tin zinc oxide, an aluminum zinc oxide, a gallium zinc oxide, a zinc tin oxide, or a gallium tin oxide. In other embodiments, the cathode electrode CE may include at least one of silver (Ag), magnesium (Mg), or a mixture thereof. However, the material of the cathode electrode CE is not necessarily limited thereto.

One of the anode electrodes AE, a portion of the light emitting structure EMS overlapping the one of the anode electrodes AE, and a portion of the cathode electrode CE overlapping the one of the anode electrodes AE may be understood as constituting one light emitting device LD (see FIG. 2). In other words, the light emitting devices of the first to third sub-pixels SP1 to SP3 may each include one anode electrode, a portion of the light emitting structure EMS overlapping therewith, and a portion of the cathode electrode CE overlapping therewith. In each of the first to third sub-pixels SP1 to SP3, holes injected from the anode electrode AE and electrons injected from the cathode electrode CE are transported into the emission layer of the light emitting structure EMS to form excitons, and light may be generated when the excitons transition from an excited state to a ground state. The luminance of light may be determined according to the amount of current flowing through the emission layer. Depending on the configuration of the emission layer, the wavelength range of the generated light may be determined.

The encapsulation layer TFE is located on the cathode electrode CE (e.g., disposed directly thereon in the third direction DR3). The encapsulation layer TFE may cover the light emitting device layer LDL and/or the pixel circuit layer PCL. The encapsulation layer TFE may be configured to prevent or mitigate oxygen and/or moisture or the like from penetrating into the light emitting device layer LDL. In an embodiment, the encapsulation layer TFE may include a structure in which one or more inorganic layers and one or more organic layers are alternately stacked (e.g., in the third direction DR3). For example, an inorganic layer may include a silicon nitride, a silicon oxide, a silicon oxynitride (SiOxNy), or the like. For example, an organic layer may include an organic insulating material such as an acrylic resin, an epoxy resin, a phenol resin, a polyamide resin, a polyimide resin, an unsaturated polyester resin, a polyphenylenether resin, a polyphenylenesulfide resin, or benzocyclobutene (BCB). However, the materials of the organic layer and the inorganic layer of the encapsulation layer TFE are not necessarily limited thereto.

In an embodiment, the encapsulation layer TFE may further include a thin film including an aluminum oxide (AlOx) in order to increase the encapsulation efficiency of the encapsulation layer TFE. The thin film including an aluminum oxide may be located on an upper surface of the encapsulation layer TFE facing the optical functional layer OFL and/or on a lower surface of the encapsulation layer TFE facing the light emitting device layer LDL.

The thin film including an aluminum oxide may be formed by an Atomic Layer Deposition (ALD) method. However, embodiments of the present disclosure are not necessarily limited thereto. The encapsulation layer TFE may further include a thin film including at least one of a variety of materials suitable for increasing encapsulation efficiency.

The optical functional layer OFL is arranged on the encapsulation layer TFE (e.g., disposed directly thereon in the third direction DR3). The optical functional layer OFL may include a color filter layer CFL and a lens array LA.

The color filter layer CFL is arranged between the encapsulation layer TFE and the lens array LA (e.g., in the third direction DR3). The color filter layer CFL is configured to filter the light emitted from the light emitting structure EMS to selectively output light of a wavelength range or color corresponding to each sub-pixel. The color filter layer CFL includes color filters CF respectively corresponding to the first to third sub-pixels SP1 to SP3, each of which is capable of passing light in a wavelength range corresponding to the corresponding sub-pixel. For example, in an embodiment the color filter corresponding to the first sub-pixel SP1 may pass light of a red color, the color filter corresponding to the second sub-pixel SP2 may pass light of a green color, and the color filter corresponding to the third sub-pixel SP3 may pass light of a blue color. Depending on the light emitted from the light emitting structure EMS of each sub-pixel, at least one or more of the color filters CF may be omitted.

The lens array LA is arranged on the color filter layer CFL (e.g., disposed directly thereon in the third direction DR3). The lens array LA may include lenses LS respectively corresponding to the first to third sub-pixels SP1 to SP3. Each of the lenses LS may output the light emitted from the light emitting structure EMS in an intended path, thereby improving light output efficiency. The lens array LA may have a relatively high refractive index. For example, the lens array LA may have a higher refractive index than the overcoat layer OC. In an embodiment, the lenses LS may include an organic material. In an embodiment, the lenses LS may include an acrylic-based material. However, the material of the lenses LS is not limited thereto.

In an embodiment, relative to the opening OP of the pixel defining layer PDL, at least one or more of the color filters CF of the color filter layer CFL and at least one or more of the lenses LS of the lens array LA may be shifted in a direction parallel to the plane defined by the first and second directions DR1 and DR2. For example, in a central region of the display area DA, the center of the color filter and the center of the lens may be aligned or overlapped with the center of the opening OP of the corresponding pixel defining layer PDL when viewed in the third direction DR3. For example, in the central region of the display area DA, the opening OP of the pixel defining layer PDL may completely overlap the corresponding color filter of the color filter layer CFL and the corresponding lens of the lens array LA. In an area adjacent to the non-display area NDA in the display area DA, the center of the color filter and the center of the lens may be shifted in a planar direction from the center of the opening OP of the corresponding pixel defining layer PDL when viewed in the third direction DR3. For example, in the area adjacent to the non-display region NDA in the display region DA, the opening OP of the pixel defining layer PDL may partially overlap the corresponding color filter of the color filter layer CFL and the corresponding lens of the lens array LA. Accordingly, in the center of the display area DA, the light emitted from the light emitting structure EMS may be efficiently output in the normal direction of the display surface. At the outer boundary of the display area DA, the light emitted from the light emitting structure EMS may be efficiently output in a direction inclined by a predetermined angle with respect to the normal direction of the display surface.

The overcoat layer OC may be located on the lens array LA (e.g., disposed directly thereon in the third direction DR3). The overcoat layer OC may cover the optical functional layer OFL, the encapsulation layer TFE, the light emitting structure EMS, and/or the pixel circuit layer PCL. The overcoat layer OC may include a variety of materials suitable for protecting the underlying layers of the overcoat layer OC from foreign materials such as dust or moisture. For example, in an embodiment the overcoat layer OC may include at least one of an inorganic insulating layer or an organic insulating layer. For example, the overcoat layer OC may include, but is not necessarily limited to, epoxy. The overcoat layer OC may have a lower refractive index than the lens array LA.

The cover window CW may be located on the overcoat layer OC (e.g., disposed directly thereon in the third direction DR3). The cover window CW is configured to protect the layers under the cover window CW. The cover window CW may have a higher refractive index than the overcoat layer OC. The cover window CW may include glass, but embodiments are not necessarily limited thereto. For example, the cover window CW may be encapsulation glass configured to protect components located below the cover window CW. In some embodiments, the cover window CW may be omitted.

According to an embodiment, the display panel DP may further include a polarizing layer and a quarter-wave plate. According to an embodiment, the display panel DP may include a plurality of quarter-wave plates. According to an embodiment, the display panel DP may include two quarter-wave plates and a polarizing layer located therebetween (e.g., in the third direction DR3). According to an embodiment, the two quarter-wave plates and the polarizing layer located therebetween may be located on the lens array LA, but embodiments of the present disclosure are not necessarily limited thereto.

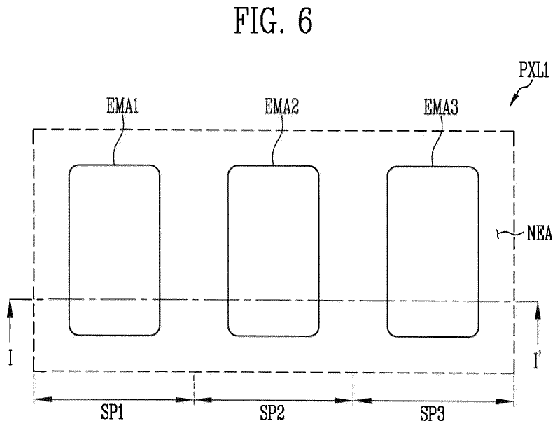

FIG. 6 is a schematic plan view of an embodiment of one of pixels of FIG. 5. In FIG. 6, the first pixel PXL1 of the first and second pixels PXL1 and PXL2 of FIG. 5 is schematically shown for clarity and brevity. The remaining pixels may be configured similarly to the first pixel PXL1.

Referring to FIGS. 5 and 6, the first pixel PXL1 may include the first to third sub-pixels SP1 to SP3 arranged in the first direction DR1.

The first sub-pixel SP1 may include a first emission area EMA1 and a non-emission area NEA around the first emission area EMA1 (e.g., in a plan view). The second sub-pixel SP2 may include a second emission area EMA2 and the non-emission area NEA around the second emission area EMA2 (e.g., in a plan view). The third sub-pixel SP3 may include a third emission area EMA3 and the non-emission area NEA around the third emission area EMA3 (e.g., in a plan view).

The first emission area EMA1 may be an area where light is emitted from a portion of the light emitting structure EMS (see FIG. 5) which corresponds to the first sub-pixel SP1. The second emission area EMA2 may be an area where light is emitted from a portion of the light emitting structure EMS which corresponds to the second sub-pixel SP2. The third emission area EMA3 may be an area where light is emitted from a portion of the light emitting structure EMS which corresponds to the third sub-pixel SP3.

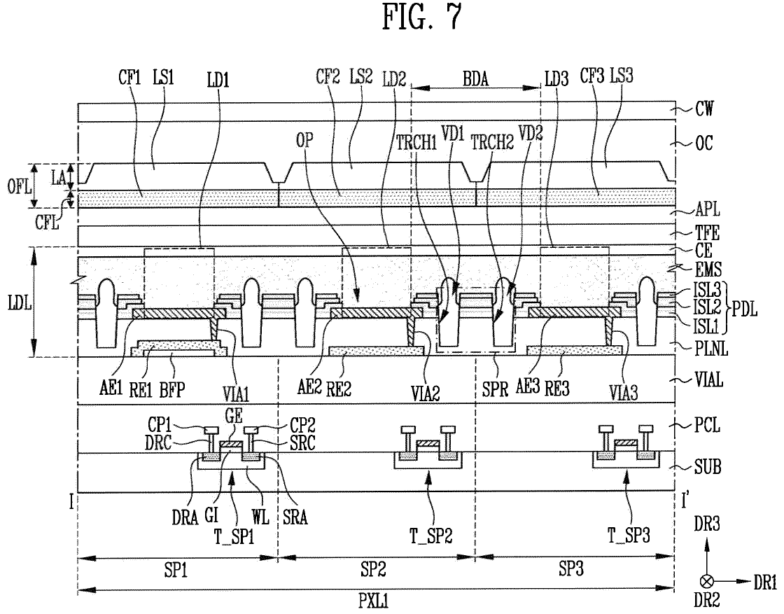

FIG. 7 is a schematic cross-sectional view taken along line I-I′ of FIG. 6 according to an embodiment of the present disclosure.

Referring to FIG. 7, the substrate SUB and the pixel circuit layer PCL located on the substrate SUB are provided.

In an embodiment, the substrate SUB may include a silicon wafer substrate formed using a semiconductor process. For example, the substrate SUB may include silicon, germanium, and/or silicon-germanium.

The pixel circuit layer PCL is located on the substrate SUB (e.g., disposed directly thereon in the third direction DR3). The substrate SUB and the pixel circuit layer PCL may include circuit devices of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see FIG. 2) of the first sub-pixel SP1, the transistor T_SP2 of the second sub-pixel SP2 may be one the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 7, for the sake of clarity and brevity, one of the transistors of each sub-pixel is shown, and the remaining circuit devices are omitted.

In an embodiment, the transistor T_SP1 of the first sub-pixel SP1 may include a source region SRA, a drain region DRA, and a gate electrode GE.

The source region SRA and the drain region DRA may be located in the substrate SUB. A well WL formed by an ion implantation process is located in the substrate SUB, and the source region SRA and the drain region DRA may be located to be spaced apart from each other (e.g., in the first direction DR1) in the well WL. A region between the source region SRA and the drain region DRA in the well WL may be defined as a channel region. The gate electrode GE overlaps the channel region between the source region SRA and the drain region DRA (e.g., in the third direction DR3), and may be located in the pixel circuit layer PCL. The gate electrode GE may be spaced apart from the well WL or the channel region by an insulating material, such as a gate insulating layer GI. The gate electrode GE may include a conductive material.

A plurality of layers included in the pixel circuit layer PCL include insulating layers and conductive patterns arranged between the insulating layers, and such conductive patterns may include first and second conductive patterns CP1 and CP2. The first conductive pattern CP1 may be electrically connected to the drain region DRA via a drain connecting portion DRC penetrating one or more insulating layers. The second conductive pattern CP2 may be electrically connected to the source region SRA via a source connecting portion SRC penetrating one or more insulating layers.

As the gate electrode GE and the first and second conductive patterns CP1 and CP2 are connected to other circuit devices and/or wirings, the transistor T_SP1 of the first sub-pixel SP1 may be provided as one of the transistors of the first sub-pixel SP1.

The transistor T_SP2 of the second sub-pixel SP2 and the transistor T_SP3 of the third sub-pixel SP3 may be configured similarly to the transistor T_SP1 of the first sub-pixel SP1.

As such, the substrate SUB and the pixel circuit layer PCL may include circuit devices of each of the first to third sub-pixels SP1 to SP3.

A via layer VIAL is located on the pixel circuit layer PCL (e.g., disposed directly thereon in the third direction DR3). The via layer VIAL covers the pixel circuit layer PCL, but may have an overall flat surface. The via layer VIAL is configured to planarize the steps on the pixel circuit layer PCL. In an embodiment, the via layer VIAL may include, but is not necessarily limited to, at least one of a silicon oxide (SiOx), a silicon nitride (SiNx), or a silicon carbon nitride (SiCN).

The light emitting device layer LDL is located on the via layer VIAL (e.g., disposed directly thereon in the third direction DR3). The light emitting device layer LDL may include first to third reflective electrodes RE1 to RE3, a planarization layer PLNL, first to third anode electrodes AE1 to AE3, the pixel defining layer PDL, the light emitting structure EMS, and the cathode electrode CE.

On the via layer VIAL, the first to third reflective electrodes RE1 to RE3 are respectively arranged to correspond to the first to third sub-pixels SP1 to SP3. Each of the first to third reflective electrodes RE1 to RE3 may directly contact a circuit device located in the pixel circuit layer PCL through a via penetrating the via layer VIAL.

The first to third reflective electrodes RE1 to RE3 may function as a full mirror which reflects the light emitted from the light emitting structure EMS toward the display surface (or the cover window CW). The first to third reflective electrodes RE1 to RE3 may include metallic materials suitable for reflecting light. The first to third reflective electrodes RE1 to RE3 may include, but are not necessarily limited to, at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected therefrom.

In an embodiment, a connecting electrode may be located below each of the first to third reflective electrodes RE1 to RE3. The connecting electrode may increase electrical connection characteristics between a corresponding reflective electrode and the circuit device of the pixel circuit layer PCL. The connecting electrode may have a multilayer structure. In an embodiment, the multilayer structure may include, but is not necessarily limited to, titanium (Ti), a titanium nitride (TiN), a tantalum nitride (TaN), and the like. In an embodiment, the corresponding reflective electrode may be located between multiple layers of the connecting electrode.

A buffer pattern BFP may be located under at least one of the first to third reflective electrodes RE1 to RE3. In an embodiment, the buffer pattern BFP may include an inorganic material such as, but is not necessarily limited to, a silicon carbon nitride. By arranging the buffer pattern BFP, the height of the corresponding reflective electrode in the third direction DR3 may be adjusted. For example, the buffer pattern BFP may be located between the first reflective electrode RE1 and the via layer VIAL (e.g., in the third direction DR3) to adjust the height of the first reflective electrode RE1.

The first to third reflective electrodes RE1 to RE3 may function as full mirrors and the cathode electrode CE may function as a half mirror. For example, each of the first to third reflective electrodes RE1 to RE3 and the cathode electrode CE may provide a resonant structure in a corresponding sub-pixel. The light emitted from the emission layer of the light emitting structure EMS may be amplified by reciprocating between the corresponding reflective electrode and the cathode electrode CE, and the amplified light may be output through the cathode electrode CE. As such, the distance between each reflective electrode and the cathode electrode CE may be understood as the resonance distance for the light emitted from the emission layer of a corresponding light emitting structure EMS.

The first sub-pixel SP1 may have the shorter resonance distance than other sub-pixels due to the buffer pattern BFP. Such an adjusted resonance distance may allow light in a particular wavelength range (e.g., red color) to be effectively and efficiently amplified. Accordingly, the first sub-pixel SP1 may effectively and efficiently output light in the corresponding wavelength range.

In FIG. 7, the buffer pattern BFP is shown to be provided to the first sub-pixel SP1 and not to the second and third sub-pixels SP2 and SP3, but embodiments of the present disclosure are not necessarily limited thereto. A buffer pattern may also be provided to at least one of the second or third sub-pixel SP2 or SP3 to adjust the resonance distance of at least the one of the second or third sub-pixel SP2 or SP3. For example, in an embodiment the first to third sub-pixels SP1 to SP3 correspond to red, green, and blue, respectively, the distance between the first reflective electrode RE1 and the cathode electrode CE may be less than the distance between the second reflective electrode RE2 and the cathode electrode CE, and the distance between the second reflective electrode RE2 and the cathode electrode CE may be less than the distance between the third reflective electrode RE3 and the cathode electrode CE.

To planarize the steps between the first to third reflective electrodes RE1 to RE3, the planarization layer PLNL may be located on (e.g., disposed directly thereon) the via layer VIAL and the first to third reflective electrodes RE1 to RE3. The planarization layer PLNL generally covers the first to third reflective electrodes RE1 to RE3 and the via layer VIAL, but may have a flat surface. In an embodiment, the planarization layer PLNL may be omitted.

On the planarization layer PLNL, the first to third anode electrodes AE1 to AE3 are arranged which respectively overlap the first to third reflective electrodes RE1 to RE3. The first to third anode electrodes AE1 to AE3 may have shapes similar to the first to third emission areas EMA1 to EMA3 of FIG. 6 when viewed in the third direction DR3 (e.g., in a plan view). The first to third anode electrodes AE1 to AE3 are connected to the first to third reflective electrodes RE1 to RE3, respectively. In an embodiment, the first anode electrode AE1 may be connected to the first reflective electrode RE1 via a first via VIA1 through the planarization layer PLNL. The second anode electrode AE2 may be connected to the second reflective electrode RE2 via a second via VIA2 through the planarization layer PLNL. The third anode electrode AE3 may be connected to the third reflective electrode RE3 via a third via VIA3 through the planarization layer PLNL.

In an embodiment, the first to third anode electrodes AE1 to AE3 may include at least one of transparent conductive materials such as an indium tin oxide (ITO), an indium zinc oxide (IZO), a zinc oxide (ZnOx), an indium gallium zinc oxide (IGZO), and an indium tin zinc oxide (ITZO). However, the material of the first to third anode electrodes AE1 to AE3 is not necessarily limited thereto. For example, the first to third anode electrodes AE1 to AE3 may include a titanium nitride.

The pixel defining layer PDL is located on (e.g., disposed directly thereon) the planarization layer PLNL and portions of the first to third anode electrodes AE1 to AE3. The pixel defining layer PDL has the opening OP which exposes a portion of each of the first to third anode electrodes AE1 to AE3. An area overlapping the pixel defining layer PDL may be understood as a boundary area BDA between sub-pixels adjacent to each other.

In an embodiment, the pixel defining layer PDL may include a plurality of inorganic insulating layers. In an embodiment, each of the plurality of inorganic insulating layers may include at least one of a silicon oxide (SiOx) or a silicon nitride (SiNx). For example, in an embodiment the pixel defining layer PDL may include a first inorganic insulating layer ISL1, a second inorganic insulating layer ISL2, and a third inorganic insulating layer ISL3, which are sequentially stacked (e.g., in the third direction DR3). The first to third inorganic insulating layers ISL1 to ISL3 may include, but are not necessarily limited to, a silicon nitride, a silicon oxide, and a silicon nitride. The first to third inorganic insulating layers ISL1 to ISL3 may have a stepped cross-section in an area adjacent to the opening OP.

In an embodiment, the pixel defining layer PDL may include a separator SPR in the boundary area BDA between adjacent sub-pixels. In other words, the separator SPR may be provided in each of the boundary areas between the sub-pixels SP of FIG. 4.

The separator SPR may cause a discontinuity to form in the light emitting structure EMS in the boundary area BDA. For example, by means of the separator SPR, the light emitting structure EMS may be broken or bent in the boundary area BDA. Accordingly, the first to third emission areas EMA1 to EMA3 of FIG. 6 respectively corresponding to the first to third sub-pixels SP1 to SP3 may be defined according to the separator SPR of the pixel defining layer PDL.

The separator SPR may be provided in or on the pixel defining layer PDL. The pixel defining layer PDL may include one or more trenches TRCH1 and TRCH2 as the separator SPR in the boundary area BDA. In an embodiment, one or more trenches TRCH1 and TRCH2 may penetrate the pixel defining layer PDL and partially penetrate the planarization layer PLNL, as shown in FIG. 7. In some embodiments, one or more trenches TRCH1 and TRCH2 may penetrate the pixel defining layer PDL and the planarization layer PLNL, and partially penetrate the via layer VIAL. In some embodiments, one or more trenches TRCH1 and TRCH2 at least partially penetrate the planarization layer PLNL and/or the via layer VIAL, and a portion of the pixel defining layer PDL may be located in one or more trenches TRCH1 and TRCH2.

In FIG. 7, it is shown that two trenches TRCH1 and TRCH2 are provided in the boundary area BDA. However, embodiments of the present disclosure are not necessarily limited thereto. For example, the pixel defining layer PDL may include one trench in the boundary area BDA. Alternatively, the pixel defining layer PDL may include three or more trenches in the boundary area BDA.

Due to the first and second trenches TRCH1 and TRCH2, discontinuities such as a first void VD1 and a second void VD2 in the boundary area BDA may be formed in the light emitting structure EMS. One or more of the plurality of layers stacked in the light emitting structure EMS may be broken or bent by the first and second voids VD1 and VD2. For example, at least one charge generation layer and at least one hole injection layer included in the light emitting structure EMS may break at the first and second voids VD1 and VD2. As such, due to the first and second trenches TRCH1 and TRCH2, the portions of the light emitting structure EMS included in the first to third sub-pixels SP1 to SP3 may be at least partially separated.

Depending on the shapes of the first and second trenches TRCH1 and TRCH2, the discontinuities formed in the light emitting structure EMS may vary.

In an embodiment, the light emitting structure EMS may be formed by a process such as vacuum deposition, inkjet printing, or the like. In this case, the same materials as the light emitting structure EMS may be located on bottom surfaces of the first and second trenches TRCH1 and TRCH2 which are adjacent to the via layer VIAL.

In an embodiment, the pixel defining layer PDL may include an additional separator such that the light emitting structure EMS further includes a discontinuity adjacent to the boundary area BDA. In an embodiment, the uppermost third inorganic insulating layer ISL3 among the first to third inorganic insulating layers ISL1 to ISL3 of the pixel defining layer PDL may have a greater width than the second inorganic insulating layer ISL2 located directly below the third inorganic insulating layer ISL3. For example, the pixel defining layer PDL may have a “T” shaped or “I” shaped cross-section in the boundary area BDA. Depending on the shape of the pixel defining layer PDL, the plurality of layers included in the light emitting structure EMS may be at least partially broken or bent in the boundary area BDA or in an area adjacent to the boundary area BDA.

The light emitting structure EMS may be located on (e.g., disposed directly thereon in the third direction DR3) the anode electrodes AE exposed by the openings OP of the pixel defining layer PDL. The light emitting structure EMS fills the opening OP of the pixel defining layer PDL and may be entirely located over the first to third sub-pixels SP1 to SP3. As described above, the light emitting structure EMS may be at least partially broken or bent in the boundary area BDA by the separator SPR. Accordingly, during the operation of the display panel DP, the current flowing out from each of the first to third sub-pixels SP1 to SP3 to a sub-pixel adjacent thereto through the layers included in the light emitting structure EMS may be reduced. Therefore, first to third light emitting devices LD1 to LD3 may operate with relatively high reliability.

The cathode electrode CE may be located on the light emitting structure EMS (e.g., disposed directly thereon in the third direction DR3). In an embodiment, the cathode electrode CE may be provided in common (e.g., commonly disposed) to the first to third sub-pixels SP1 to SP3. The cathode electrode CE may function as a half mirror which partially transmits and partially reflects the light emitted from the light emitting structure EMS.

The first anode electrode AE1, the portion of the light emitting structure EMS overlapping the first anode electrode AE1, and the portion of the cathode electrode CE overlapping the first anode electrode AE1 may constitute the first light emitting device LD1. The second anode electrode AE2, the portion of the light emitting structure EMS overlapping the second anode electrode AE2, and the portion of the cathode electrode CE overlapping the second anode electrode AE2 may constitute the second light emitting device LD2. The third anode electrode AE3, the portion of the light emitting structure EMS overlapping the third anode electrode AE3, and the portion of the cathode electrode CE overlapping the third anode electrode AE3 may constitute the third light emitting device LD3.

The encapsulation layer TFE is arranged on the cathode electrode CE (e.g., disposed directly thereon in the third direction DR3). The encapsulation layer TFE may prevent or mitigate oxygen and/or moisture or the like from penetrating into the light emitting device layer LDL.

The optical functional layer OFL is located over the encapsulation layer TFE. In an embodiment, the optical functional layer OFL may be attached to the encapsulation layer TFE via an adhesive layer APL. For example, the optical functional layer OFL may be produced separately and attached to the encapsulation layer TFE via the adhesive layer APL. The adhesive layer APL may further serve to protect the underlying layers of the adhesive layer APL, including the encapsulation layer TFE.

In an embodiment, the optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges. For example, in an embodiment the first to third color filters CF1 to CF3 may pass light of red, green, and blue colors, respectively.

In an embodiment, the first to third color filters CF1 to CF3 may partially overlap in the boundary area BDA. In some embodiments, the first to third color filters CF1 to CF3 may be spaced apart from each other, and a black matrix may be provided between the first to third color filters CF1 to CF3.

The lens array LA is arranged on the color filter layer CFL (e.g., disposed directly thereon in the third direction DR3). The lens array LA may include first to third lenses LS1 to LS3 respectively corresponding to the first to third sub-pixels SP1 to SP3. Each of the first to third lenses LS1 to LS3 outputs light emitted from the first to third light emitting devices LD1 to LD3 in an intended path, thereby increasing light output efficiency.

The overcoat layer OC may be located on the lens array LA (e.g., disposed directly thereon in the third direction DR3). The overcoat layer OC is configured to protect the layers under the overcoat layer OC from foreign materials such as dust or moisture. The cover window CW may be arranged on the overcoat layer OC (e.g., disposed directly thereon in the third direction DR3).

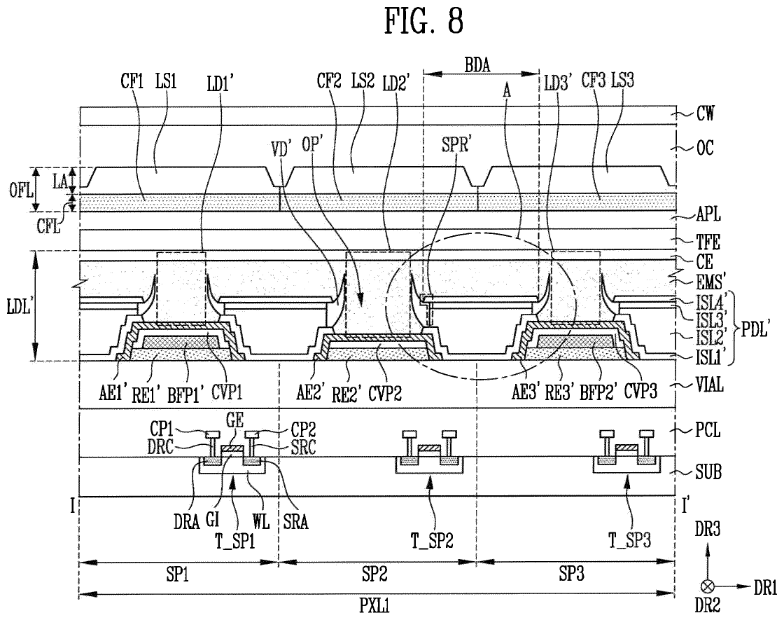

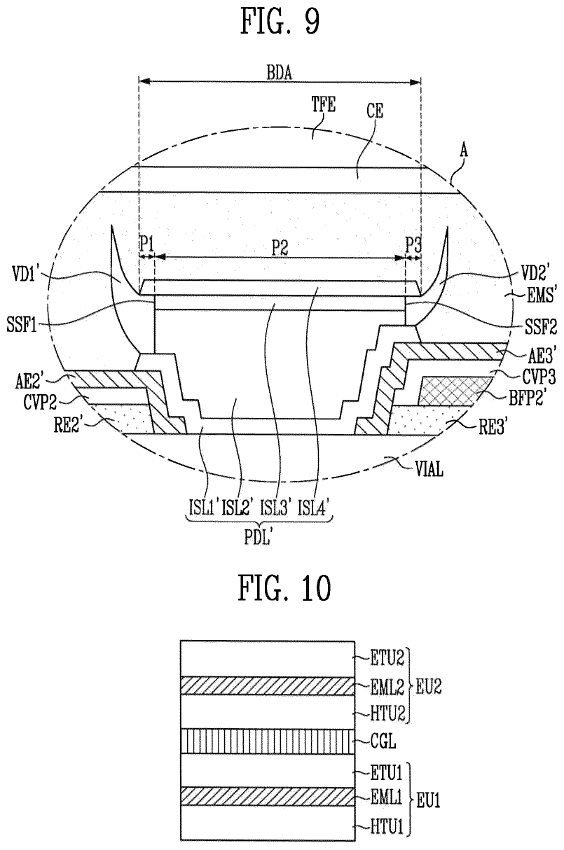

FIG. 8 is a schematic cross-sectional view taken along line I-I′ of FIG. 6 according to an embodiment of the present disclosure. FIG. 9 is a schematic enlarged view of area A of FIG. 8.

Referring to FIG. 8, the pixel circuit layer PCL and the via layer VIAL are located over the substrate SUB. The substrate SUB, the pixel circuit layer PCL, and the via layer VIAL of FIG. 8 are configured similarly to the substrate SUB, the pixel circuit layer PCL, and the via layer VIAL of FIG. 7, respectively. Hereinafter, duplicate descriptions are omitted.

A light emitting device layer LDL′ is located on the via layer VIAL (e.g., disposed directly thereon in the third direction DR3). In an embodiment, the light emitting device layer LDL′ may include first to third reflective electrodes RE1′ to RE3′, first and second buffer patterns BFP1′ and BFP2′, first to third cover patterns CVP1 to CVP3, first to third anode electrodes AE1′ to AE3′, a pixel defining layer PDL′, a light emitting structure EMS′, and the cathode electrode CE.

On the via layer VIAL, the first to third reflective electrodes RE1′ to RE3′ are respectively arranged to correspond to the first to third sub-pixels SP1 to SP3. In an embodiment, each of the first to third reflective electrodes RE1′ to RE3′ may directly contact a circuit device located in the pixel circuit layer PCL through a via penetrating the via layer VIAL.

The first to third reflective electrodes RE1′ to RE3′ are configured to reflect light emitted from the light emitting structure EMS′ towards the display surface (or the cover window CW). The first to third reflective electrodes RE1′ to RE3′ may include metallic materials suitable for reflecting light. In an embodiment, the first to third reflective electrodes RE1′ to RE3′ may include, but are not necessarily limited to, at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom.

In an embodiment, a connecting electrode may be further provided between each of the first to third reflective electrodes RE1′ to RE3′ and the via layer VIAL. The connecting electrode may increase electrical connection characteristics between a corresponding reflective electrode and the circuit device of the pixel circuit layer PCL. The connecting electrode may have a multilayer structure. In an embodiment, the multilayer structure may include, but is not necessarily limited to, titanium (Ti), aluminum (Al), a titanium nitride (TiN), a tantalum nitride (TaN), and the like. In an embodiment, the corresponding reflective electrode may be located between multiple layers of the connecting electrode.

A buffer pattern may be arranged on at least one of the first to third reflective electrodes RE1′ to RE3′. In an embodiment, the first and second buffer patterns BFP1′ and BFP2′ may be located on (e.g., disposed directly thereon in the third direction DR3) the first and third reflective electrodes RE1′ and RE3′, respectively. The heights of the first and third anode electrodes AE1′ and AE3′ in the third direction DR3 may be adjusted by the first and second buffer patterns BFP1′ and BFP2′. In an embodiment, the first and second buffer patterns BFP1′ and BFP2′ may include inorganic materials such as, but not necessarily limited to, a silicon oxide (SiOx) and a silicon nitride (SiNx).

The first to third cover patterns CVP1 to CVP3 may be respectively arranged on (e.g., disposed directly thereon) the first to third reflective electrodes RE1′ to RE3′. In the first sub-pixel SP1, the first cover pattern CVP1 is arranged on the first reflective electrode RE1′ and the first buffer pattern BFP1′. In the second sub-pixel SP2, the second cover pattern CVP2 is arranged on the second reflective electrode RE2′. In the third sub-pixel SP3, the third cover pattern CVP3 is arranged on the third reflective electrode RE3′ and the second buffer pattern BFP2′. The first to third cover patterns CVP1 to CVP3 may be formed after the formation of the first and second buffer patterns BFP1′ and BFP2′ during a manufacturing process. The first to third cover patterns CVP1 to CVP3 may include the same material as the first and second buffer patterns BFP1′ and BFP2′. For example, in an embodiment, the first to third cover patterns CVP1 to CVP3 may include an inorganic material such as a silicon oxide (SiOx) and a silicon nitride (SiNx), but embodiments are not necessarily limited thereto.

The first to third anode electrodes AE1′ to AE3′ are respectively arranged on the first to third cover patterns CVP1 to CVP3. In an embodiment, the first anode electrode AE1′ may cover the first cover pattern CVP1, the first buffer pattern BFP1′, and the first reflective electrode RE1′. The second anode electrode AE2′ may cover the second cover pattern CVP2 and the second reflective electrode RE2′. The third anode electrode AE3′ may cover the third cover pattern CVP3, the second buffer pattern BFP2′, and the third reflective electrode RE3′.

The first to third anode electrodes AE1′ to AE3′ may be electrically connected to the first to third reflective electrodes RE1′ to RE3′, respectively. For example, each anode electrode may be connected to the end (e.g., an edge) of a corresponding reflective electrode. However, embodiments of the present disclosure are not necessarily limited thereto. To increase electrical connection characteristics between the anode electrode and the reflective electrode, the anode electrode may be connected to the reflective electrode in various ways.

In an embodiment, the first to third anode electrodes AE1′ to AE3′ may include at least one of transparent conductive materials such as an indium tin oxide (ITO), an indium zinc oxide (IZO), a zinc oxide (ZnOx), an indium gallium zinc oxide (IGZO), or an indium tin zinc oxide (ITZO). However, the material of the first to third anode electrodes AE1′ to AE3′ is not necessarily limited thereto. For example, the first to third anode electrodes AE1′ to AE3′ may include a titanium nitride.

The first to third anode electrodes AE1′ to AE3′ may have shapes similar to the first to third emission areas EMA1 to EMA3 of FIG. 6 when viewed in the third direction DR3 (e.g., in a plan view).

The first to third anode electrodes AE1′ to AE3′ and the cathode electrode CE may partially reflect incident light. The light emitted from the emission layer of the light emitting structure EMS′ may be amplified by reciprocating between the corresponding anode electrode and the cathode electrode CE, and may be output through the cathode electrode CE. For example, each anode electrode and the cathode electrode CE may provide a resonant structure in a corresponding sub-pixel. In this case, the distance between each anode electrode and the cathode electrode CE may be understood as the resonance distance for the light emitted from the emission layer of the corresponding light emitting structure EMS′.

In an embodiment, the first to third sub-pixels SP1 to SP3 may correspond to red, green, and blue, respectively. In this case, the height of each of the first and third anode electrodes AE1′ and AE3′ in the third direction DR3 may be higher than the height of the second anode electrode AE2′ by the first and second buffer patterns BFP1′ and BFP2′. Accordingly, the first and third sub-pixels SP1 and SP3 may have the shorter resonance distance than the second sub-pixel SP2 due to the first and second buffer patterns BFP1′ and BFP2′. In this way, the resonance distance of each sub-pixel may be adjusted so that light in a wavelength range of a corresponding color is effectively and efficiently amplified.

FIG. 8 shows that the first and second buffer patterns BFP1′ and BFP2′ are located below portions (e.g., an upper portion) of the first and third anode electrodes AE1′ and AE3′, respectively, although embodiments are not necessarily limited thereto. For example, one of the first and second buffer patterns BFP1′ and BFP2′ may be omitted. As another example, both the first and second buffer patterns BFP1′ and BFP2′ may be omitted. In this case, each of the resonance distances between anode electrodes and the cathode electrode CE may be the same. As another example, a buffer pattern may be located below each of the first to third anode electrodes AE1′ to AE3′. In this case, the buffer patterns respectively located below the anode electrodes may have different thicknesses, and thus the resonance distance between each anode electrode and the cathode electrode CE may vary. In this way, by providing a buffer pattern below at least one of the first to third anode electrodes AE1′ to AE3′ for adjusting the height of a corresponding anode electrode, the resonance distance in each sub-pixel may be optimized.

The pixel defining layer PDL′ is located on (e.g., disposed directly thereon) the via layer VIAL and portions of the first to third anode electrodes AE1′ to AE3′. The pixel defining layer PDL′ has an opening OP′ which exposes a portion of each of the first to third anode electrodes AE1′ to AE3′. An area overlapping the pixel defining layer PDL′ may be understood as the boundary area BDA between sub-pixels adjacent to each other.

The pixel defining layer PDL′ may include a plurality of inorganic insulating layers stacked sequentially (e.g., in the third direction DR3). In an embodiment, each of the plurality of inorganic insulating layers may include at least one of a silicon oxide (SiOx) or a silicon nitride (SiNx). However, embodiments of the present disclosure are not necessarily limited thereto. For example, the pixel defining layer PDL′ may include an organic insulating layer.

In an embodiment, the pixel defining layer PDL′ may include first to fourth inorganic insulating layers ISL1′ to ISL4′. The first inorganic insulating layer ISL1′ may cover the portions of the first to third anode electrodes AE1′ to AE3′ and the via layer VIAL. The second inorganic insulating layer ISL2′ is located on (e.g., disposed directly thereon) the first inorganic insulating layer ISL1′, the third inorganic insulating layer ISL3′ is located on (e.g. disposed directly thereon) the second inorganic insulating layer ISL2′, and the fourth inorganic insulating layer ISL4′ is located on (e.g., disposed directly thereon) the third inorganic insulating layer ISL3′. In an embodiment, the first and third inorganic insulating layers ISL1′ and ISL3′ may include a silicon nitride (SiNx) and the second and fourth inorganic insulating layers ISL2′ and ISL4′ may include a silicon oxide (SiOx), although embodiments are not necessarily limited thereto. In an embodiment, the first inorganic insulating layer ISL1′ may be omitted.

The pixel defining layer PDL′ may include a separator SPR′ in the boundary area BDA between adjacent sub-pixels. The separator SPR′ may cause a discontinuity, such as a void VD′, to form in the light emitting structure EMS′. Due to the discontinuity, at least one or more of the plurality of layers included in the light emitting structure EMS′ may break or bend.

The fourth inorganic insulating layer ISL4′ may have a greater width (e.g., in the first direction DR1) than each of the second and third inorganic insulating layers ISL2′ and ISL3′. In this case, side surfaces of the second to fourth inorganic insulating layers ISL2′ to ISL4′ adjacent to the opening OP′ may be provided as the separator SPR′.

Referring to FIG. 9 together with FIG. 8, the fourth inorganic insulating layer ISL4′ may include first to third portions P1 to P3. The second portion P2 may completely overlap the second and third inorganic insulating layers ISL2′ and ISL3′ (e.g., in the third direction DR3). The first portion P1 protrudes from the second portion P2 in a direction opposite to the first direction DR1. The third portion P3 protrudes from the second portion P2 in the first direction DR1. As such, the width of the fourth inorganic insulating layer ISL4′ may be greater than that of each of the second and third inorganic insulating layers ISL2′ and ISL3′. For example, during a manufacturing process, the second and third inorganic insulating layers ISL2′ and ISL3′ may be undercut so as not to include portions overlapping the first and third portions P1 and P3. For example, each of the first and third portions P1 and P3 of the fourth inorganic insulating layer ISL4′ may have an eaves shape above the second and third inorganic insulating layers ISL2′ and ISL3′ (e.g., in a cross-sectional view).

In the boundary area BDA, the second and third inorganic insulating layers ISL2′ and ISL3′ may have the same width as each other (e.g., in the first direction DR1). However, embodiments of the present disclosure are not necessarily limited thereto, and the second and third inorganic insulating layers ISL2′ and ISL3′ may have different widths from each other. For example, in some embodiments the second inorganic insulating layer ISL2′ may have a greater width than the third inorganic insulating layer ISL3′ (e.g., in the first direction DR1). As another example, the third inorganic insulating layer ISL3′ may have a greater width than the second inorganic insulating layer ISL2′ (e.g., in the first direction DR1).

In the second sub-pixel SP2, the first portion P1 of the fourth inorganic insulating layer ISL4′ and a first side surface SSF1 of the second and third inorganic insulating layers ISL2′ and ISL3′ may be provided as one separator SPR′. Accordingly, a first void VD1′, which is adjacent to the first portion P1 of the fourth inorganic insulating layer ISL4′, may be formed in the light emitting structure EMS′. In the third sub-pixel SP3, the third portion P3 of the fourth inorganic insulating layer ISL4′ and a second side surface SSF2 of the second and third inorganic insulating layers ISL2′ and ISL3′ may be provided as another separator SPR′. Accordingly, a second void VD2′, which is adjacent to the third portion P3 of the fourth inorganic insulating layer ISL4′ may be formed in the light emitting structure EMS′.

One or more of the plurality of layers stacked in the light emitting structure EMS′ may be broken or bent by the first and second voids VD1′ and VD2′. For example, at least one charge generation layer and at least one hole injection layer included in the light emitting structure EMS′ may be broken by the first and second voids VD1′ and VD2′. As such, due to the separator SPR′, portions of the light emitting structure EMS′ included in the first to third sub-pixels SP1 to SP3 may be at least partially separated from one another.

The pixel defining layer PDL′ may include an additional separator such that the light emitting structure EMS′ further includes a discontinuity in the boundary area BDA. In an embodiment, the pixel defining layer PDL′ may include one or more trenches as a separator in the boundary area BDA. The trenches may penetrate one or more of the first to fourth inorganic insulating layers ISL1′ to ISL4′. Due to the trenches, one or more of the plurality of layers stacked in the light emitting structure EMS′, for example at least one charge generation layer and at least one hole injection layer, may be broken or bent. In an embodiment, the light emitting structure EMS′ may have a structure in which three emission portions each including an emission layer are stacked, and two charge generation layers may be arranged between the three emission portions. In such embodiments, the pixel defining layer PDL′ may include one or more trenches in the boundary area BDA.

Referring again to FIG. 8, the light emitting structure EMS′ may be arranged on the anode electrodes AE exposed by the opening OP′ of the pixel defining layer PDL′. The light emitting structure EMS′ fills the opening OP′ of the pixel defining layer PDL′ and may be arranged entirely over the first to third sub-pixels SP1 to SP3. As described above, the light emitting structure EMS′ may be broken or bent by the separator SPR′ in the boundary area BDA or in an area adjacent to the boundary area BDA. Accordingly, during the operation of the display panel DP, the current flowing out from each of the first to third sub-pixels SP1 to SP3 to a sub-pixel adjacent thereto through the layers included in the light emitting structure EMS′ may be reduced. Thus, first to third light emitting devices LD1′ to LD3′ may operate with relatively high reliability.

In an embodiment, the light emitting structure EMS′ may include two emission portions stacked sequentially (e.g., in the third direction DR3) and each of the emission portions may include an emission layer configured to generate light according to an applied current. In an embodiment, the light emitting structure EMS′ may include three emission portions stacked sequentially (e.g., in the third direction DR3) and each of the emission portions may include an emission layer configured to generate light according to an applied current. In such embodiments, a charge generation layer may be arranged between the emission portions.

In an embodiment, the light emitting structure EMS′ may be formed by a process such as vacuum deposition, inkjet printing, or the like.

The cathode electrode CE may be located on the light emitting structure EMS′ (e.g., disposed directly thereon in the third direction DR3). In an embodiment, the cathode electrode CE may be provided in common to the first to third sub-pixels SP1 to SP3.

The first anode electrode AE1′, a portion of the light emitting structure EMS′ overlapping the first anode electrode AE1′, and a portion of the cathode electrode CE overlapping the first anode electrode AE1′ may constitute the first light emitting device LD1′. The second anode electrode AE2′, a portion of the light emitting structure EMS′ overlapping the second anode electrode AE2′, and a portion of the cathode electrode CE overlapping the second anode electrode AE2′ may constitute the second light emitting device LD2′. The third anode electrode AE3′, a portion of the light emitting structure EMS′ overlapping the third anode electrode AE3′, and a portion of the cathode electrode CE overlapping the third anode electrode AE3′ may constitute the third light emitting device LD3′.

The encapsulation layer TFE is arranged on the cathode electrode CE (e.g., directly thereon in the third direction DR3). The encapsulation layer TFE may prevent or mitigate oxygen and/or moisture or the like from penetrating into the light emitting device layer LDL′.

The adhesive layer APL, the optical functional layer OFL, the overcoat layer OC, and the cover window CW are arranged over the encapsulation layer TFE (e.g., in the third direction DR3). The adhesive layer APL, the optical functional layer OFL, the overcoat layer OC, and the cover window CW are configured similarly to the adhesive layer APL, the optical functional layer OFL, the overcoat layer OC, and the cover window CW of FIG. 7, respectively. Duplicate descriptions of these components are omitted.

FIG. 10 is a schematic cross-sectional view showing an embodiment of a portion of a light emitting structure included in one of the first to third light emitting devices of FIG. 7 or 8.

Referring to FIG. 10, the light emitting structure may have a tandem structure in which first and second emission portions EU1 and EU2 are stacked (e.g., in the third direction DR3). The light emitting structure may be configured substantially identically in each of the first to third light emitting devices LD1 to LD3 of FIG. 7.

Each of the first and second emission portions EU1 and EU2 may include at least one emission layer which generates light according to an applied current. In an embodiment, the first emission portion EU1 may include a first emission layer EML1, a first electron transport portion ETU1, and a first hole transport portion HTU1. The first emission layer EML1 may be located between the first electron transport portion ETU1 and the first hole transport portion HTU1. The second emission portion EU2 may include a second emission layer EML2, a second electron transport portion ETU2, and a second hole transport portion HTU2. The second emission layer EML2 may be located between the second electron transport portion ETU2 and the second hole transport portion HTU2.

In an embodiment, each of the first and second hole transport portions HTU1 and HTU2 may include at least one of a hole injection layer or a hole transport layer, and may further include a hole buffer layer, an electron blocking layer, and the like as necessary. The first and second hole transport portions HTU1 and HTU2 may have the same configuration or different configurations from each other.

Each of the first and second electron transport portions ETU1 and ETU2 may include at least one of an electron injection layer or an electron transport layer, and may further include an electron buffer layer, a hole blocking layer, and the like as necessary. The first and second electron transport portions ETU1 and ETU2 may have the same configuration or different configurations from each other.

In an embodiment, a connecting layer, which may be provided in the form of a charge generation layer CGL, may be arranged between the first and second emission portions EU1 and EU2 (e.g., in the third direction DR3) to connect (e.g., electrically connect) the first and second emission portions EU1 and EU2 to one another. In an embodiment, the charge generation layer CGL may have a stacked structure of a p-dopant layer and an n-dopant layer. For example, the p-dopant layer may include p-type dopants such as HAT-CN, TCNQ, or NDP-9, and the n-dopant layer may include an alkali metal, an alkaline earth metal, a lanthanide-based metal, or a combination thereof. However, embodiments of the present disclosure are not necessarily limited thereto.

In an embodiment, the first emission layer EML1 and the second emission layer EML2 may generate light of different colors from each other. The light emitted from each of the first emission layer EML1 and the second emission layer EML2 may be mixed together and visually recognized as white light. For example, the first emission layer EML1 may generate light of a blue color, and the second emission layer EML2 may generate light of a yellow color. In an embodiment, the second emission layer EML2 may include a structure in which a first sub-emission layer configured to generate light of a red color and a second sub-emission layer configured to generate light of a green color are stacked. The light of the red color and the light of the green color may be mixed to provide light of the yellow color. In this case, an intermediate layer configured to perform a function of transporting holes and/or a function of blocking the transport of electrons may be further located between the first and second sub-emission layers.

In some embodiments, the first emission layer EML1 and the second emission layer EML2 may generate light of the same color as each other.

In an embodiment, the light emitting structure may be formed by a process such as vacuum deposition, inkjet printing, or the like, but embodiments are not necessarily limited thereto.

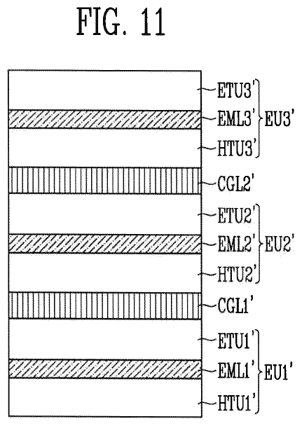

FIG. 11 is a schematic cross-sectional view showing an embodiment of a portion of a light emitting structure included in one of the first to third light emitting devices of FIG. 7 or 8.

Referring to FIG. 11, the light emitting structure may have a tandem structure in which first to third emission portions EU1′ to EU3′ are stacked. The light emitting structure may be configured substantially identically in each of the first to third light emitting devices LD1 to LD3 of FIG. 7.

Each of the first to third emission portions EU1′ to EU3′ may include an emission layer which generates light according to an applied current. The first emission portion EU1′ may include a first emission layer EML1′, a first electron transport portion ETU1′, and a first hole transport portion HTU1′. The first emission layer EML1′ may be located between the first electron transport portion ETU1′ and the first hole transport portion HTU1′ (e.g., in the third direction DR3). The second emission portion EU2′ may include a second emission layer EML2′, a second electron transport portion ETU2′, and a second hole transport portion HTU2′. The second emission layer EML2′ may be located between the second electron transport portion ETU2′ and the second hole transport portion HTU2′ (e.g., in the third direction DR3). The third emission portion EU3′ may include a third emission layer EML3′, a third electron transport portion ETU3′, and a third hole transport portion HTU3′. The third emission layer EML3′ may be located between the third electron transport portion ETU3′ and the third hole transport portion HTU3′.

In an embodiment, each of the first to third hole transport portions HTU1′ to HTU3′ may include at least one of a hole injection layer or a hole transport layer, and may further include a hole buffer layer, an electron blocking layer, and the like as necessary. The first to third hole transport portions HTU1′ to HTU3′ may have the same configuration or different configurations from each other.

In an embodiment, each of the first to third electron transport portions ETU1′ to ETU3′ may include at least one of an electron injection layer or an electron transport layer, and may further include an electron buffer layer, a hole blocking layer, and the like as necessary. The first to third electron transport portions ETU1′ to ETU3′ may have the same configuration or different configurations from each other.

A first charge generation layer CGL1′ is arranged between the first emission portion EU1′ and the second emission portion EU2′ (e.g., in the third direction DR3). A second charge generation layer CGL2′ is arranged between the second emission portion EU2′ and the third emission portion EU3′ (e.g., in the third direction DR3).

In an embodiment, the first to third emission layers EML1′ to EML3′ may generate light of different colors from each other. The light emitted from each of the first to third emission layers EML1′ to EML3′ may be mixed and visually recognized as white light. For example, the first emission layer EML1′ may generate light of a blue color, the second emission layer EML2′ may generate light of a green color, and the third emission layer EML3′ may generate light of a red color.

In SOME embodiments, two or more of the first to third emission layers EML1′ to EML3′ may generate light of the same color.

Unlike embodiments shown in FIGS. 10 and 11, the light emitting structure of FIG. 7 or 8 may include one emission portion in each of the first to third light emitting devices LD1 to LD3. In this case, the emission portion included in each of the first to third light emitting devices LD1 to LD3 may be configured to emit light of different colors from ach other. For example, in an embodiment the emission portion of the first light emitting device LD1 may emit light of a red color, the emission portion of the second light emitting device LD2′ may emit light of a green color, and the emission portion of the third light emitting device LD3 may emit light of a blue color. In this case, the emission portions of the first to third sub-pixels SP1 to SP3 are separated from each other, and each of the emission portions may be located in the opening (see OP of FIG. 7 or OP′ of FIG. 8) of the pixel defining layer (see PDL of FIG. 7 or PDL′ of FIG. 8). In this case, at least one or more of the color filters CF1 to CF3 may be omitted.

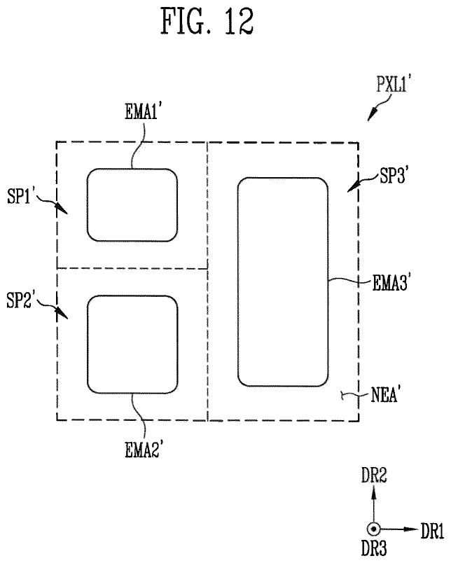

FIG. 12 is a schematic plan view showing an embodiment of one of the pixels of FIG. 5.

Referring to FIG. 12, a first pixel PXL1′ may include first to third sub-pixels SP1′ to SP3′.

The first sub-pixel SP1′ may include a first emission area EMA1′ and a non-emission area NEA′ around the first emission area EMA1′ (e.g., in a plan view). The second sub-pixel SP2′ may include a second emission area EMA2′ and the non-emission area NEA′ around the second emission area EMA2′ (e.g., in a plan view). The third sub-pixel SP3′ may include a third emission area EMA3′ and the non-emission area NEA′ around the third emission area EMA3′ (e.g., in a plan view).

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

In an embodiment, the second sub-pixel SP2′ may have a greater area than the first sub-pixel SP1′ (e.g., in a plan view), and the third sub-pixel SP3′ may have a greater area than the second sub-pixel SP2′ (e.g., in a plan view). Accordingly, the second emission area EMA2′ may have a greater area than the first emission area EMA1′, and the third emission area EMA3′ may have a greater area than the second emission area EMA2′. However, embodiments of the present disclosure are not necessarily limited thereto. For example, the first and second sub-pixels SP1′ and SP2′ may have substantially the same area as each other, and the third sub-pixel SP3′ may have a greater area than each of the first and second sub-pixels SP1′ and SP2′. As such, the areas of the first to third sub-pixels SP1′ to SP3′ may be variously modified according to embodiments.

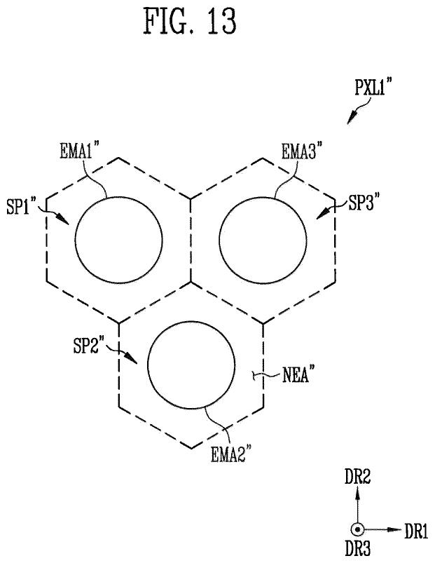

FIG. 13 is a schematic plan view showing an embodiment of one of the pixels of FIG. 5.

Referring to FIG. 13, a first sub-pixel SP1″ may include a first emission area EMA1″ and a non-emission area NEA″ around the first emission area EMA1″ (e.g., in a plan view). A second sub-pixel SP2″ may include a second emission area EMA2″ and the non-emission area NEA″ around the second emission area EMA2″ (e.g., in a plan view). A third sub-pixel SP3″ may include a third emission area EMA3″ and the non-emission area NEA″ around the third emission area EMA3″ (e.g., in a plan view).

The first to third sub-pixels SP1″ to SP3″ may have polygonal shapes when viewed in the third direction DR3 (e.g., in a plan view). For example, the shapes of the first to third sub-pixels SP1″ to SP3″ may be hexagons as shown in FIG. 13.

The first to third emission areas EMA1″ to EMA3″ may have circular shapes when viewed in the third direction DR3 (e.g., in a plan view). However, embodiments of the present disclosure are not necessarily limited thereto. For example, each of the first to third emission areas EMA1″ to EMA3″ may have a polygonal shape (e.g., in a plan view).

The first and third sub-pixels SP1″ and SP3″ may be arranged in the first direction DR1. The second sub-pixel SP2″ may be arranged with respect to the first sub-pixel SP1″ in a direction inclined by an acute angle (e.g., a diagonal direction) with respect to the second direction DR2.

The arrangement of the sub-pixels shown in FIGS. 6, 12, or 13 is illustrative, and embodiments of the present disclosure are not necessarily limited thereto. Each pixel includes two or more sub-pixels, which may be arranged in various ways, and each of the sub-pixels may have various shapes, and each of emission areas of the sub-pixels may also have various shapes.

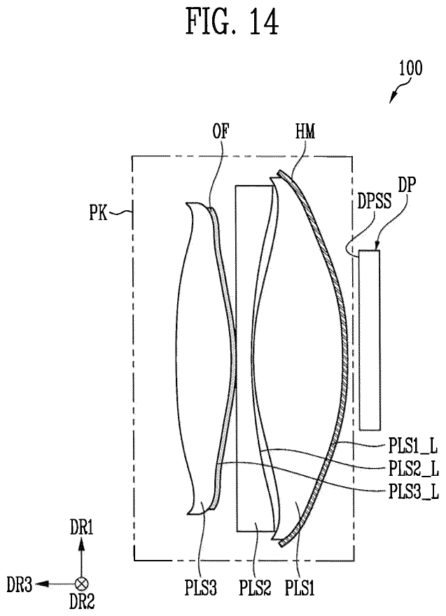

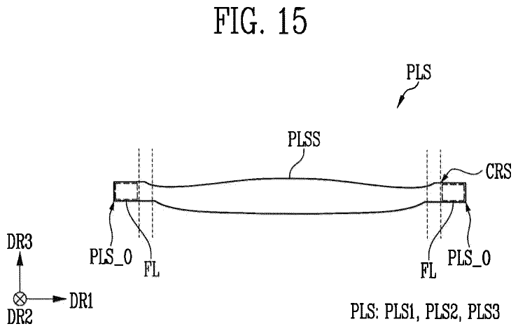

FIG. 14 is a schematic cross-sectional view showing an embodiment of the display device 100. FIG. 15 is a schematic cross-sectional view showing an embodiment of a lens PLS. The lens PLS of FIG. 15 is a lens which can be in direct contact with an optical film OF of FIG. 14 when the optical film OF is located, and may correspond to one of first to third lenses PLS1 to PLS3. For example, the lens PLS is a lens included in a pancake lens PK, and may correspond to the first lens PLS1, the second lens PLS2, or the third lens PLS3.

Referring to FIG. 14, the display device 100 may further include the pancake lens PK. A pancake lens is a lens using folded optics, and may refer to a lens structure in which a plurality of lenses and polarizing devices are overlapped with each other. The number of lenses and polarizing devices of the pancake lens PK is not necessarily limited to a specific example, but will be described below with reference to an embodiment in which the pancake lens PK includes three lenses PLS1, PLS2, and PLS3 for convenience of explanation.

The pancake lens PK may be located on a display surface DPSS of the display panel DP. The display surface DPSS may correspond to a surface from which light is emitted from the display panel DP.

In an embodiment, the pancake lens PK may include the first lens PLS1, the second lens PLS2, the third lens PLS3, a half mirror HM, and the optical film OF. However, as described above, embodiments of the present disclosure are not necessarily limited thereto, and according to an embodiment, the pancake lens PK may include two lenses or four or more lenses.

The first lens PLS1 may be located on the display panel DP with respect to the third direction DR3. The first lens PLS1 may be located adjacent to the display surface DPSS of the display panel DP. For example, the first lens PLS1 may be located closer to the display surface DPSS of the display panel DP than the third lens PLS3 (e.g., in the third direction DR3). For example, the distance between the first lens PLS1 and the display surface DPSS (e.g., in the third direction DR3) may be less than the distance between the third lens PLS3 and the display surface DPSS (e.g., in the third direction DR3).

The second lens PLS2 may be located on the first lens PLS1 with respect to the third direction DR3. The second lens PLS2 may be located between the first lens PLS1 and the third lens PLS3 (e.g., in the third direction DR3).

The third lens PLS3 may be located on the second lens PLS2 with respect to the third direction DR3. The third lens PLS3 may be located closer to the eye of the user of the display device 100 than another lens. For example, the third lens PLS3 may be located closer to the user's eye than the first lens PLS1 and the second lens PLS2. For example, the distance between the third lens PLS3 and the user's eyes may be less than the distance between the first lens PLS1 and the user's eyes.

In an embodiment, each of the first to third lenses PLS1 to PLS3 may include at least one of plastic or glass. Each of the first to third lenses PLS1 to PLS3 may have a structure in which a convex lens and a concave lens including at least one of plastic or glass are combined. As a result, the first to third lenses PLS1 to PLS3 may enlarge an image.

Referring to FIG. 15, at least one surface PLSS of each of the first to third lenses PLS1 to PLS3 may be a curved surface. For example, at least one surface PLSS of each of the first to third lenses PLS1 to PLS3 may have a bent configuration. The surface PLSS may be a surface to which the optical film OF is attached when the optical film OF is disposed thereon.

The curved surface (e.g., the surface PLSS) of the lens PLS may include a curvature change area CRS. According to an embodiment, the curvature change area CRS may correspond to an area including an inflection point at which the curvature of the curved surface changes. Alternatively, according to an embodiment, the curvature change area CRS may correspond to an area in which the curvature of the curved surface changes rapidly, for example, an area in which a slope of the curved surface varies by greater than or equal to about 10°. According to an embodiment, the number of curvature change areas CRS may be one or more, depending on the structure of the lens PLS.

The surface of the lens PLS is a curved surface and includes the curvature change area CRS, so that the display device 100 according to an embodiment of the present disclosure may reduce the risk of the occurrence of inflection of a Chief Ray Angle (CRA). As a result, the quality of an image provided to the user may be increased. For example, the risk of distortion of the image provided to the user and chromatic aberration of the image may be reduced.

The lens PLS may include a flange portion FL. The flange portion FL may be defined as an area a predetermined distance away from an outermost edge PLS_O which is defined as a rim (e.g., an edge) of the lens PLS. The predetermined distance may be changed according to characteristics of the lens PLS (for example, a size of the lens PLS), and the flange portion FL may refer to an area in which a manufacturing device for manufacturing the display device 100 and the lens PLS may be coupled during a manufacturing process of the display device 100.

Referring back to FIG. 14, the half mirror HM may be located between the display panel DP and the first lens PLS1 (e.g., in the third direction DR3). The half mirror HM may transmit light incident in the third direction DR3 (e.g., light incident from below the half mirror HM) and reflect light incident in a direction opposite to the third direction DR3 (e.g., light incident from above the half mirror HM).

The optical film OF may be located on a surface of at least one of the first to third lenses PLS1 to PLS3. The optical film OF may be attached (or adhered) to the surface of at least one of the first to third lenses PLS1 to PLS3. For example, in an embodiment the optical film OF may be thermally bonded to or may be attached (or adhered) through an adhesive layer to the surface of at least one of the first to third lenses PLS1 to PLS3.

An embodiment of FIG. 14 shows that the optical film OF is attached (or adhered) to the third lens PLS3. However, embodiments of the present disclosure are not necessarily limited thereto, and according to an embodiment, the optical film OF may be attached (or adhered) to the first lens PLS1 and/or may be attached (or adhered) to the second lens PLS2.

For example, in an embodiment the optical film OF may be attached (or adhered) to at least one of a lower surface PLS1_L of the first lens PLS1, a lower surface PLS2_L of the second lens PLS2, or a lower surface PLS3_L of the third lens PLS3. Alternatively, according to an embodiment, the optical film OF may be attached (or adhered) to upper surfaces of the first to third lenses PLS1 to PLS3. The lower surfaces PLS1_L to PLS3_L of the first to third lenses PLS1 to PLS3 are defined as surfaces located closer to the display panel DP among respective surfaces of the first to third lenses PLS1 to PLS3, and the upper surfaces may be defined as surfaces located farther from the display panel DP among the respective surfaces of the first to third lenses PLS1 to PLS3.

The optical film OF may be a polarizing layer. For example, in an embodiment the optical film OF may include at least one of a quarter-phase retardation layer, a linear polarizing layer, a reflective polarizing layer, and an absorbing polarizing layer. The optical film OF may be a film in which at least two of a phase retardation layer, a linear polarizing layer, a reflective polarizing layer, and an absorbing polarizing layer are combined, or may be a film composed of one of a phase retardation layer, a linear polarizing layer, a reflective polarizing layer, and an absorption polarizing layer.

The quarter-phase retardation layer may convert the polarization state of light which has passed through the quarter-phase retardation layer from linear polarization to circular polarization, or from circular polarization to linear polarization. The linear polarizing layer may linearly polarize the polarization state of light which has passed through the linear polarizing layer. Each of the reflective polarizing layer and the absorbing polarizing layer may reflect or absorb light of one component which has passed through each of the reflective polarizing layer and the absorbing polarizing layer.

Depending on the configuration of the optical film OF, a single optical film OF may be provided in the pancake lens PK, or a plurality of optical films OF may be provided according to embodiments. In an embodiment in which the single optical film OF is provided, the optical film OF may be located on (or attached to) one surface of one of the first to third lenses PLS1 to PLS3. In an embodiment in which the plurality of optical films OF are provided, the optical films OF may be located on (or attached to) at least two surfaces of upper surfaces and lower surfaces of the first to third lenses PLS1 to PLS3.

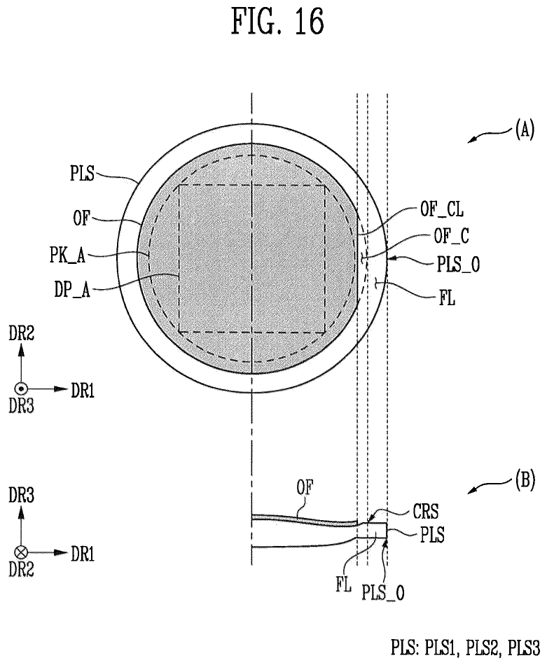

According to the display device 100 of the present disclosure, even when the optical film OF is located on a curved surface, a risk of bubbles being generated between the optical film OF and the lens PLS when the optical film OF is formed may be reduced. This will be described below with reference to FIG. 16 and subsequent drawings.

FIGS. 16 to 18 are schematic diagrams illustrating an arrangement of the lens PLS and the optical film OF according to an embodiment. In each of FIGS. 16 to 18, (A) is a plan view showing the arrangement of the lens PLS and the optical film OF according to an embodiment and (B) is a cross-sectional view showing the arrangement of the lens PLS and the optical film OF according to an embodiment.

Referring to FIG. 16, the optical film OF may have a cut surface OF_CL. The cut surface OF_CL is a surface formed by cutting a portion OF_C of the optical film OF and may be planar, according to an embodiment. The cut surface OF-CL may be the edge surface of the optical film OF where the optical film has been cut due the performance of a cutting process. For example, the cut surface OF_CL may have the shape of a line that is not curved (e.g., a straight line) in a plan view. According to an embodiment, the cut portion OF_C of the optical film OF may have an arcuate shape in a plan view. For example, in a plan view, the cut portion OF_C of the optical film OF may have the shape of a figure including curves and straight lines.

Hereinafter, the “plane” in the context of the expression “in a plan view” may be defined as a plane parallel to the display panel DP.

The cut portion OF_C of the optical film OF may be arranged between a curvature effective diameter area DP_A of the lens PLS and the flange portion FL in a plan view. For example, the cut portion OF_C may not overlap with the curvature effective diameter area DP_A and the flange portion FL of the lens PLS in a plan view.

The curvature effective diameter area DP_A of the lens PLS may correspond to an area in which the display panel DP is arranged. For example, in a plan view, the curvature effective diameter area DP_A of the lens PLS may completely overlap the area in which the display panel DP is arranged. For example, in a plan view, the area and the shape of the curvature effective diameter area DP_A of the lens PLS may correspond to (e.g., be the same as) the area and the shape of the display panel DP, respectively. The curvature effective diameter area DP_A may be changed according to characteristics of the display panel DP.

In a plan view, the optical film OF may completely overlap the curvature effective diameter area DP_A. For example, the optical film OF may overlap an entirety of the curvature effective diameter area DP_A in a plan view. The optical film OF may completely overlap the display panel DP in a plan view. The optical film OF may have an area greater than an area of the curvature effective diameter area DP_A in a plan view. The optical film OF may have the area greater than an area of the display panel DP in a plan view.

The optical film OF overlaps a curvature maximum effective diameter area PK_A in a plan view and may be arranged across the curvature maximum effective diameter area PK_A. For example, in a plan view, the optical film OF may be arranged to extend from the center of the curvature effective diameter area DP_A to the outer boundary of the curvature maximum effective diameter area PK_A. For example, in a plan view, the optical film OF may be arranged to extend further in a direction (e.g., the first direction DR1 or the second direction DR2) in which the plane extends from the center of the curvature effective diameter area DP_A towards the direction in which the curvature maximum effective diameter area PK_A is located.

In a plan view, the optical film OF may extend to the outer boundary of the curvature maximum effective diameter area PK_A, and in a plan view, at least a portion of the optical film OF may be arranged in an area outside the curvature maximum effective diameter area PK_A. In a plan view, the optical film OF is arranged across the curvature maximum effective diameter area PK_A, but may not overlap with a partial area of the lens PLS. For example, the partial area which does not overlap with the optical film OF may correspond to the outermost edge PLS_O of the lens PLS. The optical film OF may not overlap with the outermost edge PLS_O of the lens PLS in a plan view.

The curvature maximum effective diameter area PK_A may correspond to (e.g., be the same as) an area in which an image is displayed to a user through the display device 100. For example, the curvature maximum effective diameter area PK_A may be an area in which light emitted from the display panel DP passes through the pancake lens PK such that an image is displayed to and recognized by the user's eyes. For example, the curvature maximum effective diameter area PK_A may correspond to an area through which the light from the display panel DP is transmitted the most or through which the light which may be central to the user's acquisition of an image. In a plan view, the curvature maximum effective diameter area PK_A may have a greater area than the curvature effective diameter area DP_A.

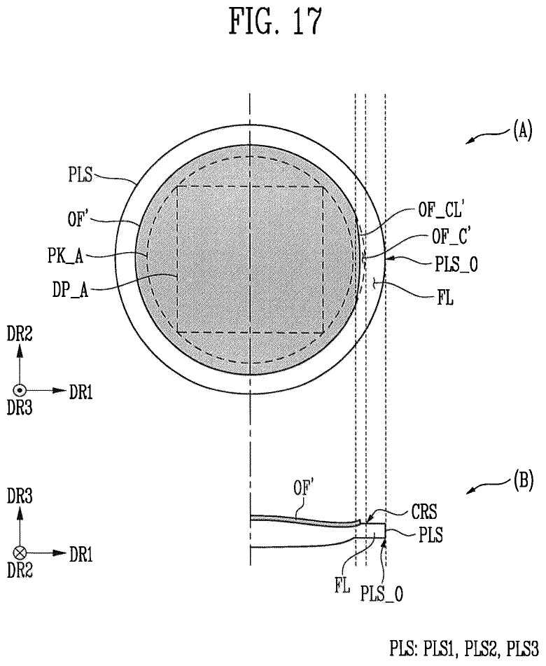

Referring to FIG. 17, an optical film OF′ according to an embodiment is shown. The optical film OF′ according to this embodiment differs from the optical film OF described above in that a cut surface OF_CL′ is different. Therefore, any repetitive descriptions already mentioned above shall be briefly mentioned or omitted.

The cut surface OF_CL′ may be a curved surface, according to an embodiment. For example, the cut surface OF_CL′ may have the shape of a curved line (e.g., a curve) in a plan view. According to an embodiment, a cut portion OF_C′ of the optical film OF′ may have the shape of a figure including a plurality of curved surfaces in a plan view.

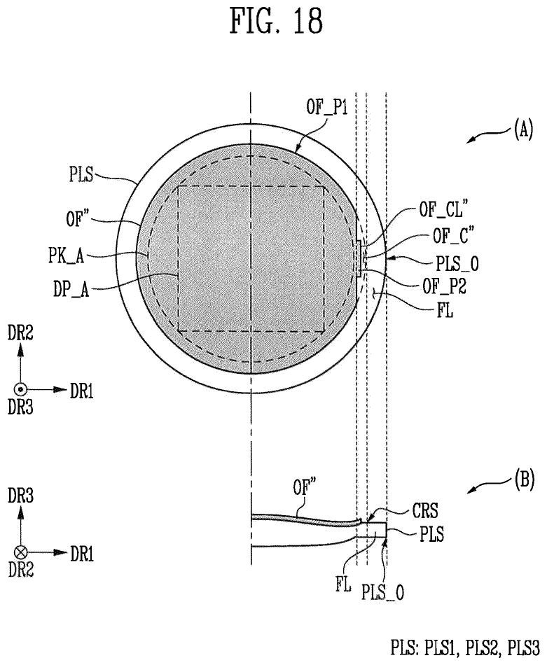

Referring to FIG. 18, an optical film OF″ according to an embodiment is shown. The optical film OF″ according to this embodiment is different from the optical film OF described above in that a cut surface OF_CL″ is different. Therefore, any repetitive descriptions already mentioned above shall be briefly mentioned or omitted.

The optical film OF″ may include a first portion OF_P1 and a second portion OF_P2 projecting from the first portion OF_P1 in a plan view. The first portion OF_P1 includes a portion of the cut surface OF_CL″ and the second portion OF_P2 may include the remaining portion of the cut surface OF_CL″, which is not included in the first portion OF_P1.

The first portion OF_P1 may have the shape corresponding to the optical film OF or OF′ described above. According to an embodiment, the second portion OF_P2 may have the shape of at least one of a rectangle, a circle, or an ellipse in a plan view. The shape of the cut portion OF_C, OF_C′, or OF_C″ of the optical film OF, OF′, or OF″ according to an embodiment of the present disclosure may be variously modified as long as the cut portion OF_C, OF_C′, or OF_C″ is arranged between the curvature effective diameter area DP_A and the flange portion FL in a plan view.

In an embodiment in which the second portion OF_P2 has the rectangular shape in a plan view, the cut surface OF_CL″ may include a plurality of flat surfaces. When the second portion OF_P2 has the shape of at least one of a circle or an ellipse in a plan view, the cut surface OF_CL″ may include a flat surface and a curved surface. For example, the cut surface OF_CL, OF_CL′, or OF_CL″ may include at least one of a flat surface or a curved surface.

FIGS. 16 to 18 show embodiments in which the optical film OF, OF′, or OF″ is cut in only one area. For example, the number of the cut portion OF_C, OF_C′, or OF_C″ of the optical film OF, OF′, or OF″ is shown to be one. However, embodiments of the present disclosure are not necessarily limited thereto. According to an embodiment, the optical film OF, OF′, or OF″ may include a plurality of cut areas, each of which may include a cut surface OF_CL, OF_CL′, or OF_CL″.

In a plan view, the cut surface OF_CL, OF_CL′, or OF_CL″ of the optical film OF, OF′, or OF″ is located between the curvature effective diameter area DP_A and the flange portion FL, so that the display device 100 according to an embodiment of the present disclosure may reduce a risk of bubbles being generated when forming the optical film OF, OF′, or OF″.

In a comparative embodiment in which the optical film OF, OF′, or OF″ is attached (or adhered) directly to a curved surface without forming the cut surface OF_CL, OF_CL′, or OF_CL″, bubbles may penetrate into an edge area of the optical film OF, OF′, or OF″, and thus the reliability of the display device 100 may be deteriorated. For example, low-quality images may be provided to the user.

In contrast, the display device 100 according to embodiments of the present disclosure may form the optical film OF, OF′, or OF″ such that the cut surface OF_CL, OF_CL′, or OF_CL″ of the optical film OF, OF′, or OF″ is arranged between the curvature effective diameter area DP_A and the flange portion FL in a plan view, thereby reducing a risk of bubbles being generated when the optical film OF, OF′, or OF″ is attached (or adhered) to the lens PLS.

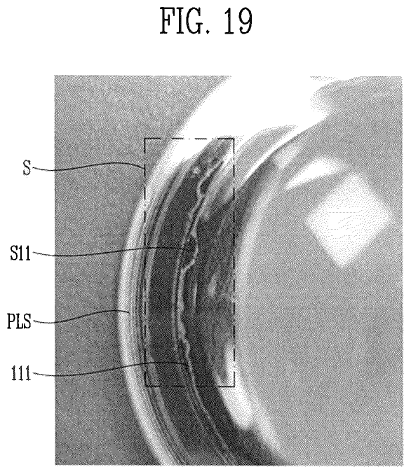

FIG. 19 is a diagram illustrating a comparative embodiment where an optical film 111 which does not include a cut area is arranged on a lens. FIG. 20 is a diagram illustrating a case where an optical film OF, OF′, or OF″ which includes a cut area is arranged on a lens.

Referring to FIG. 19, in a comparative embodiment when the optical film 111 which does not include the cut area is arranged on the lens PLS, when area S is checked (e.g., imaged), it can be seen that an edge S11 of the optical film 111 is corrugated. The corrugation is formed by the penetration of bubbles during the formation of the optical film 111, which may reduce the reliability of the display device 100.

On the other hand, referring to FIG. 20, when the optical film OF, OF′, or OF″ including the cut area (e.g., the above-described cut surface OF_CL, OF_CL′, or OF_CL″) is arranged on the lens PLS, when area S′ is checked (e.g., imaged), it can be seen that an edge of the optical film OF, OF′, or OF″ is not corrugated. Accordingly, it can be seen that the optical film OF, OF′, or OF″ according to embodiments of the present disclosure reduce a risk of bubbles penetrating when forming the optical film OF, OF′, or OF″.

In addition, according to the display device 100 of an embodiment of the present disclosure, a polarization axis of the optical film OF, OF′, or OF″ may be observed without separately arranging a mark for the polarization axis recognition on the optical film OF, OF′, or OF″. For example, the polarization axis of the optical film OF, OF′, or OF″ may be checked (e.g., imaged) by using information of an angle formed by the cut surface OF_CL, OF_CL′, or OF_CL″ and the polarization axis when the cut surface OF_CL, OF_CL′, or OF_CL″ of the optical film OF, OF′, or OF″ is formed. For example, in a case where the cut surface OF_CL, OF_CL′, or OF_CL″ of the optical film OF, OF′, or OF″ is formed so as to be arranged parallel to the polarization axis of the optical film OF, OF′, or OF″, when a direction in which the cut surface OF_CL, OF_CL′, or OF_CL″ is arranged is checked (e.g., imaged), a direction in which the polarization axis of the optical film OF, OF′, or OF″ is arranged may be checked.

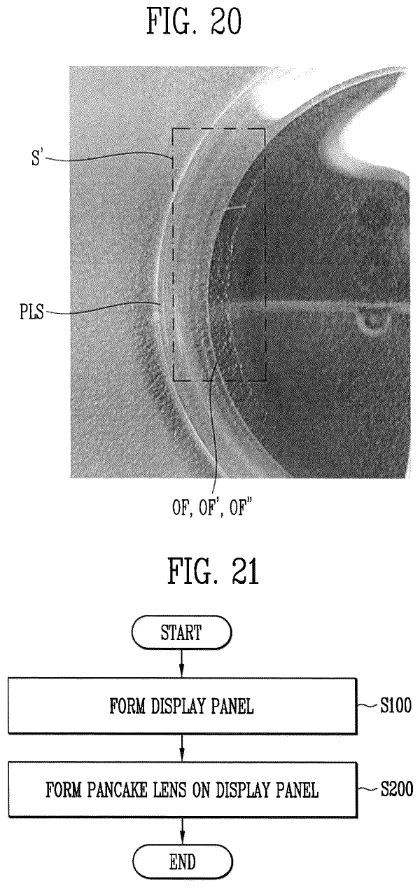

Hereinafter, a method of manufacturing the display device 100 will be described with reference to FIG. 21. Any repetitive descriptions already mentioned above shall be briefly mentioned or omitted.

FIG. 21 is a flowchart illustrating a method of manufacturing the display device 100 according to an embodiment. Referring to FIG. 21, a method of manufacturing the display device 100 according to an embodiment may include forming a display panel in block S100 and forming a pancake lens on the display panel S200.

Referring to FIG. 21, in combination with FIGS. 1 to 13, forming the display panel in block S100 may include forming the pixel circuit layer PCL on the substrate SUB, forming the light emitting device LD, and forming the encapsulation layer TFE.

In forming the pixel circuit layer PCL on the substrate SUB, circuit devices may be patterned on the substrate SUB, and the pixel circuit layer PCL may be provided.

According to an embodiment, a conductive layer, an insulating layer, and the like on the substrate SUB may be formed based on a general process for manufacturing a semiconductor device. For example, in an embodiment the conductive layer or the insulating layer on the substrate SUB may be formed by a photolithography process, may be etched by various methods (e.g., wet etching, dry etching, or the like), and may be deposited by various methods (e.g., sputtering, chemical vapor deposition, or the like). However, embodiments of the present disclosure are not necessarily limited to specific examples.

In forming the pixel circuit layer PCL on the substrate SUB, the transistors T_SP1 to T_SP3 may be patterned on the substrate SUB. The via layer VIAL may then be arranged on the pixel circuit layer PCL. Furthermore, according to an embodiment, the first to third reflective electrodes RE1 to RE3 may be patterned on the via layer VIAL, and according to an embodiment, the planarization layer PLNL may be arranged on the via layer VIAL.

Referring to FIG. 21, in combination with FIGS. 7 to 9, in forming the light emitting device LD, the anode electrode AE, the light emitting structure EMS, and the cathode electrode CE may be formed to form the first to third light emitting devices LD1 to LD3.

In forming the light emitting device LD, the first to third anode electrodes AE1 to AE3 may be patterned, and the pixel defining layer PDL overlapping the first to third anode electrodes AE1 and AE3 may also be patterned.

According to an embodiment (see FIG. 7 and the like), the trenches TRCH1 and TRCH2 may be formed as the separator SPR, and the light emitting structure EMS may be formed. In this embodiment, at least a portion of the light emitting structure EMS may be broken (e.g., bent). The cathode electrode CE may then be formed on the light emitting structure EMS (e.g., formed directly thereon in the third direction DR3).

In forming the encapsulation layer TFE, the encapsulation layer TFE may be formed on the light emitting device LD. The underlying layers of the encapsulation layer TFE may be passivated.

Thereafter, according to an embodiment, the color filter layer CFL, the optical functional layer OFL, the overcoat layer OC, and the cover window CW may be arranged (e.g., in the third direction DR3), and the display panel DP according to an embodiment may be provided.

Referring to FIG. 21, in combination with FIGS. 14 to 18, forming the pancake lens in block S200 may include arranging the first lens PLS1, the second lens PLS2, and the third lens PLS3, arranging the half mirror HM, and arranging the optical film OF, OF′, or OF″ on the surface of at least one of the first to third lenses PLS1 to PLS3. At least one of the first to third lenses PLS1 to PLS3 on which the optical film OF, OF′, or OF″ is arranged may correspond to the lens PLS described above.

The half mirror HM, the first lens PLS1, the second lens PLS2, and the third lens PLS3 may be sequentially arranged on the display panel DP, but embodiments of the present disclosure are not necessarily limited thereto.

Arranging the optical film OF, OF′, or OF″ may include forming the optical film OF, OF′, or OF″ on the surface of at least one of the first to third lenses PLS1 to PLS3.

Referring to FIGS. 16 to 18, forming the optical film OF, OF′, or OF″ may include removing the portion OF_C, OF_C′, or OF_C″ of a base optical film. Removing the portion OF_C, OF_C′, or OF_C″ of the base optical film may include forming the optical film OF, OF′, or OF″ having the cut surface OF_CL, OF_CL′, or OF_CL″ by cutting the portion OF_C, OF_C′, or OF_C″ of the base optical film. In an embodiment, the portion OF_C, OF_C′, or OF_C″ of the base optical film may be cut by laser, knife, or the like.

The base optical film is an optical film before being cut, and the base optical film may have a greater area than the curvature maximum effective diameter area PK_A and a smaller area than the lens PLS in a plan view. For example, the base optical film may completely overlap with the curvature maximum effective diameter area PK_A in a plan view and may not overlap with an area of the lens PLS. For example, the base optical film may not overlap with the outermost edge PLS_O of the lens PLS.

In an embodiment, the forming of the optical film OF, OF′, or OF″ may include laminating the cut optical film OF, OF′, or OF″ on the surface PLSS of the lens PLS. The laminating of the cut optical film OF, OF′, or OF″ may include attaching the optical film OF, OF′, or OF″ to the surface PLSS of the lens PLS through heat or through an adhesive layer. In an embodiment, the adhesive layer may include at least one of a Pressure Sensitive Adhesive (PSA) or an Optically Clear Adhesive (OCA).

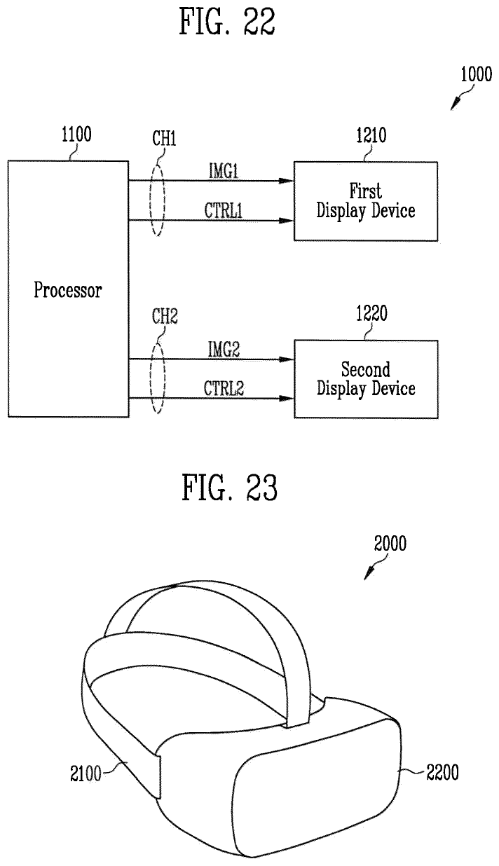

FIG. 22 is a block diagram illustrating an embodiment of a display system 1000.

Referring to FIG. 22, the display system 1000 may include a processor 1100 and one or more display devices, such as the first and second display devices 1210 and 1220.

The processor 1100 may perform various tasks and calculations. In an embodiment, the processor 1100 may include an application processor, a graphics processor, a microprocessor, a central processing unit (CPU), or the like. The processor 1100 may be connected to other components of the display system 1000 through a bus system to control other components. The display system 1000 may have a memory having stored application programs for execution by the processor.

In FIG. 22, the display system 1000 is shown to include first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this embodiment, the first image data IMG1 and the first control signal CTRL1 may be respectively provided as the input image data IMG and the control signal CTRL of FIG. 1.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this embodiment, the second image data IMG2 and the second control signal CTRL2 may be respectively provided as the input image data IMG and the control signal CTRL of FIG. 1.

The display system 1000 may include a computing system which provides image display functions for various different electronic devices, such as a portable computer, a mobile phone, a smart phone, a tablet personal computer (PC), a smart watch, a watch phone, a portable multimedia player (PMP), a navigation device, and an ultra mobile personal computer (UMPC). In addition, the display system 1000 may include at least one of a Head-Mounted Display (HMD) device, a Virtual Reality (VR) device, a Mixed Reality (MR) device, or an Augmented Reality (AR) device. However, embodiments of the present disclosure are not necessarily limited thereto and the electronic device that the display device DD may be applied to may be various different small-sized, medium-sized or large-sized electronic devices.

FIG. 23 is a schematic perspective view showing an application example of the display system 1000 of FIG. 22.

Referring to FIG. 23, the display system 1000 of FIG. 22 may be applied to a head-mounted display device 2000. The head-mounted display device 2000 may be a wearable electronic device which can be worn on a user's head.

The head-mounted display device 2000 may include a head-mounted band 2100 and a display device storage case 2200. The head-mounted band 2100 may be connected to the display device storage case 2200. The head-mounted band 2100 may include a horizontal band and/or a vertical band for securing the head-mounted display device 2000 to the user's head. The horizontal band may be configured to surround a side of the user's head, and the vertical band may be configured to surround an upper portion of the user's head. However, embodiments of the present disclosure are not necessarily limited thereto. For example, the head-mounted band 2100 may be implemented in the form of an eyeglass frame, a helmet, or the like.

The display device storage case 2200 may store the first and second display devices 1210 and 1220 of FIG. 22. The display device storage case 2200 may further store the processor 1100 of FIG. 22.

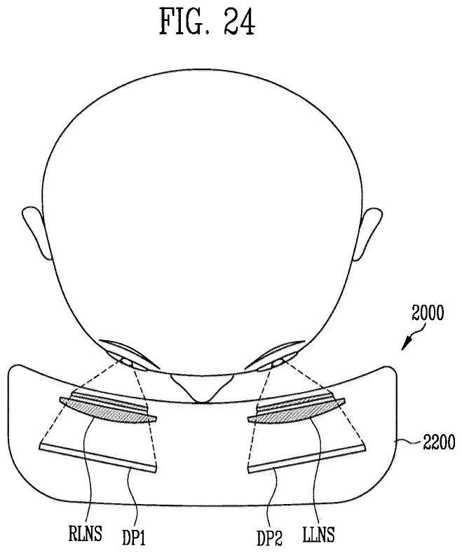

FIG. 24 is a schematic diagram illustrating the head-mounted display device 2000 of FIG. 23 worn by a user.

Referring to FIG. 24, a first display panel DP1 of the first display device 1210 and a second display panel DP2 of the second display device 1220 are arranged in the head-mounted display device 2000. The head-mounted display device 2000 may further include one or more lenses LLNS and RLNS.

In the display device storage case 2200, the right eye lens RLNS may be located between the first display panel DP1 and the right eye of the user. In the display device storage case 2200, the left eye lens LLNS may be located between the second display panel DP2 and the left eye of the user.

The image output from the first display panel DP1 may be shown to the right eye of the user through the right eye lens RLNS. The right eye lens RLNS may refract light from the first display panel DP1 toward the right eye of the user. The right eye lens RLNS may perform an optical function for adjusting a viewing distance between the first display panel DP1 and the right eye of the user.

The image output from the second display panel DP2 may be shown to the left eye of the user through the left eye lens LLNS. The left eye lens LLNS may refract light from the second display panel DP2 toward the left eye of the user. The left eye lens LLNS may perform an optical function for adjusting a viewing distance between the second display panel DP2 and the left eye of the user.

In an embodiment, each of the right eye lens RLNS and the left eye lens LLNS may include an optical lens having a pancake-shaped cross-section (e.g., the pancake lens PK described above). In an embodiment, each of the right eye lens RLNS and the left eye lens LLNS may include a multi-channel lens including sub-areas having different optical properties. In this embodiment, each display panel outputs images respectively corresponding to the sub-areas of the multi-channel lens, and each of the output images may be shown to the user through the corresponding sub-area.

Although non-limiting embodiments and applications have been described herein, other embodiments and variations may be derived from the above descriptions. Accordingly, the spirit of the present disclosure is not limited to the described embodiments, but extends to various modifications, and equivalents.

According to an embodiment of the present disclosure, a display device capable of reducing a risk of inflection of a Chief Ray Angle (CRA) occurring, a display system, and a method of manufacturing the display device may be provided.

According to embodiments of the present disclosure, a display device capable of reducing a risk of bubbles being generated when forming an optical film, a display system, and a method of manufacturing the display device may be provided.

However, the effects according to embodiments of the present disclosure are not limited to the effects described above, and wider variety of effects are included herein.

What is claimed is:

1. A display device comprising:
a display panel; and
a pancake lens arranged on the display panel,
wherein the pancake lens comprises:
a plurality of lenses; and
an optical film arranged on a surface of at least one of the plurality of lenses,
wherein the optical film has a cut surface where a portion of the optical film has been cut, and
wherein in a plan view, the cut surface does not overlap with the display panel.

2. The display device according to claim 1, wherein the surface of the at least one of the plurality of lenses is a curved surface.

3. The display device according to claim 2, wherein:
the curved surface includes a curvature change area; and
the curvature change area corresponds to an area including an inflection point where a curvature of the curved surface changes, or corresponds to an area where a slope of the curved surface varies in an amount greater than or equal to about 10°.

4. The display device according to claim 3, wherein the optical film is attached to the surface of the at least one of the plurality of lenses.

5. The display device according to claim 1, wherein in the plan view, the optical film completely overlaps with the display panel and does not overlap with a partial area of the at least one of the plurality of lenses.

6. The display device according to claim 5, wherein the partial area corresponds to an outermost edge of the at least one of the plurality of lenses.

7. The display device according to claim 1, wherein:
in the plan view, the cut surface is arranged between a curvature effective diameter area of the at least one of the plurality of lenses and a flange portion of the at least one of the plurality of lenses,
wherein in the plan view, the curvature effective diameter area corresponds to an area that the display panel is arranged, and
wherein the flange portion corresponds to an area that is a predetermined distance away from an outermost edge of the at least one of the plurality of lenses.

8. The display device according to claim 1, wherein the cut surface includes at least one of a flat surface or a curved surface in the plan view.

9. The display device according to claim 1, wherein:
the optical film includes a first portion and a second portion projecting from the first portion in the plan view; and
the second portion has a shape of at least one of a circle, a rectangle, or an ellipse in the plan view.

10. The display device according to claim 1, wherein the optical film includes a plurality of cut areas.

11. The display device according to claim 1, wherein the optical film is thermally bonded to, or attached through an adhesive layer to, the surface of the at least one of the plurality of lenses.

12. The display device according to claim 1, wherein:
the plurality of lenses includes at least one of plastic or glass; and
the optical film is a polarizing layer.

13. The display device according to claim 1, wherein the display panel includes an organic light-emitting diode (OLED).

14. A method of manufacturing a display device, the method comprising:
forming a display panel; and
forming a pancake lens on the display panel,
wherein the forming of the pancake lens comprises:
arranging a plurality of lenses; and
arranging an optical film on a surface of at least one of the plurality of lenses,
wherein the arranging of the optical film comprises:
forming the optical film having a cut surface by cutting a portion of a base optical film, and
wherein in a plan view, the cut surface does not overlap with the display panel.

15. The method according to claim 14, wherein the arranging of the optical film further comprises:
attaching the optical film to the surface of the at least one of the plurality of lenses by thermal bonding or through an adhesive layer,
wherein the surface of the at least one of the plurality of lenses is a curved surface,
wherein the curved surface includes a curvature change area, and
wherein the curvature change area corresponds to an area including an inflection point where a curvature of the curved surface changes, or corresponds to an area where a slope of the curved surface varies in an amount greater than or equal to about 10°.

16. The method according to claim 15, wherein in the plan view, the optical film completely overlaps with the display panel and does not overlap with a partial area of the at least one of the plurality of lenses,
wherein the partial area corresponds to an outermost edge of the at least one of the plurality of lenses,
wherein in the plan view, the cut surface is arranged between a curvature effective diameter area of the at least one of the plurality of lenses and a flange portion of the at least one of the plurality of lenses,
wherein in the plan view, the curvature effective diameter area corresponds to an area that the display panel is arranged, and
wherein the flange portion corresponds to an area that is a predetermined distance away from the outermost edge of the at least one of the plurality of lenses.

17. The method according to claim 16, wherein the cut surface includes at least one of a flat surface or a curved surface in the plan view.

18. An electronic device, comprising:
a processor;
a memory having stored application programs for execution by the processor; and
a display device, comprising:
a display panel; and
a pancake lens arranged on the display panel,
wherein the pancake lens comprises:
a plurality of lenses; and
an optical film arranged on a surface of at least one of the plurality of lenses,
wherein the surface of the at least one of the plurality of lenses is a curved surface,
wherein the optical film has a cut surface where a portion of the optical film has been cut,
wherein in a plan view, the cut surface is arranged between a curvature effective diameter area of the at least one of the plurality of lenses and a flange portion of the at least one of the plurality of lenses,
wherein in the plan view, the curvature effective diameter area corresponds to an area that the display panel is arranged, and
wherein the flange portion corresponds to an area that is a predetermined distance away from an outermost edge of the at least one of the plurality of lenses.

19. The electronic device according to claim 18, wherein the display system includes at least one of a Virtual Reality (VR) device, a Mixed Reality (MR) device, or an Augmented Reality (AR) device.

20. The electronic device according to claim 19, wherein in the plan view, the optical film overlaps with an area that an image is displayed to a user and does not overlap with the outermost edge of the at least one of the plurality of lenses.
